(19) United States
(12) Patent Application Publication
(10) Pub. No.: US 2025/0261469 A1
(43) Pub. Date: Aug. 14, 2025

(54) SOLID-STATE IMAGING DEVICE

(71) Applicant: SONY SEMICONDUCTOR SOLUTIONS CORPORATION, KANAGAWA (JP)

(72) Inventor: JUN OKUNO, KANAGAWA (JP)

(21) Appl. No.: 18/859,147

(22) PCT Filed: Mar. 14, 2023
(86) PCT No.: PCT/JP2023/009841

§ 371 Date: Oct. 22, 2024

(30) Foreign Application Priority Data
Apr. 28, 2022 (JP) 2022-075086

(51) Int. Cl. H10F 39/00; H01L 23/522; H04N 25/79; H10F 39/18

(52) U.S. Cl. CPC H10F 39/811; H01L 23/5223; H04N 25/79; H10F 39/182; H10F 39/8063; H10F 39/809

(57) ABSTRACT

Provided is a solid-state imaging device capable of reducing cost related to a capacitor. A solid-state imaging device of the present disclosure includes: a first substrate; a photoelectric conversion unit provided in the first substrate; a floating diffusion unit provided in the first substrate; a pixel transistor electrically connected to the floating diffusion unit; and a capacitor including a first electrode electrically connected or connectable to the pixel transistor, a second electrode different from the first electrode, and a first ferroelectric film or a first antiferroelectric film provided between the first electrode and the second electrode.

### TECHNICAL FIELD

The present disclosure relates to a solid-state imaging device.

### BACKGROUND ART

A voltage domain type solid-state imaging device realizes a global shutter function by simultaneously converting charges generated in a photodiode into voltages in all pixels and holding the voltages until reading is completed. In this case, charges are simultaneously transferred from the photodiode to a floating diffusion unit in all the pixels, and a current flows through an amplifying transistor simultaneously in all the pixels. The above voltage is held in a capacitor at a post stage of the amplifying transistor. Thereafter, signals are sequentially read from the capacitors of these pixels. Although this capacitor desirably has a large capacity, an increase in the capacity of the capacitor may increase the cost of the solid-state imaging device.

Furthermore, in order to realize a moving image capturing at a high frame rate and a pseudo global shutter function, a frame memory including a capacitor as a storage element may be provided in the solid-state imaging device. However, when it is attempted to provide a frame memory in a voltage domain type solid-state imaging device, forming both a capacitor and a memory may increase the cost of the solid-state imaging device.

### CITATION LIST

### Patent Document

Patent Document 1: U.S. Patent Application Publication No. 2020/0279876

### Non-Patent Document

Non-Patent Document 1: H. Tsugawa et al., IEDM Dig. Tech. Papers, December 2017.

### SUMMARY OF THE INVENTION

### Problems to be Solved by the Invention

The present disclosure provides a solid-state imaging device capable of reducing the cost related to a capacitor.

### Solutions to Problems

A solid-state imaging device of a first aspect of the present disclosure includes: a first substrate; a photoelectric conversion unit provided in the first substrate; a floating diffusion unit provided in the first substrate; a pixel transistor electrically connected to the floating diffusion unit; and a capacitor including a first electrode electrically connected or connectable to the pixel transistor, a second electrode different from the first electrode, and a first ferroelectric film or a first antiferroelectric film provided between the first electrode and the second electrode. As a result, for example, it is possible to reduce the cost related to the capacitor, for example, it is possible to form a large-capacity capacitor or a high-performance capacitor at low cost.

Furthermore, in the first aspect, the pixel transistor may be an amplifying transistor having a gate electrically connected to the floating diffusion unit and a source or a drain electrically connected to or connectable to the first electrode. As a result, for example, the cost related to the capacitor of the voltage domain type solid-state imaging device can be reduced.

Furthermore, in the first aspect, the first electrode may be electrically connectable to the pixel transistor via a switch transistor. As a result, for example, the cost related to the capacitor of the voltage domain type solid-state imaging device can be reduced.

Furthermore, in the first aspect, the first ferroelectric film or the first antiferroelectric film may contain hafnium (Hf), zirconium (Zr), niobium (Nb), scandium (Sc), yttrium (Y), lanthanum (La), germanium (Ge), or silicon (Si). Thus, for example, a suitable ferroelectric film or antiferroelectric film can be formed.

Furthermore, in the first aspect, the capacitor may be provided on a first surface side of the first substrate, and the solid-state imaging device may further include a lens provided on a second surface side of the first substrate. As a result, for example, the capacitor can be applied to a back-illuminated type solid-state imaging device.

Furthermore, the solid-state imaging device of the first aspect may further include a second substrate bonded to the first substrate, and the pixel transistor and the capacitor may be provided between the first substrate and the second substrate. As a result, for example, the capacitor can be applied to a solid-state imaging device configured using two substrates.

Furthermore, in the first aspect, the pixel transistor may be provided in a first insulating film provided on the first substrate, and the capacitor may be provided in a second insulating film provided on the second substrate and located between the second substrate and the first insulating film. As a result, for example, the capacitor can be applied to a solid-state imaging device configured using two substrates.

Furthermore, the solid-state imaging device of the first aspect may further include a third substrate provided between the first substrate and the second substrate, and the capacitor may be provided between the second substrate and the third substrate. As a result, for example, the capacitor can be applied to a solid-state imaging device configured using three substrates.

Furthermore, in the first aspect, a capacity of the capacitor is controlled to be set to only one of a plurality of types of values. As a result, for example, a capacitor other than the paraelectric capacitor can be used like a paraelectric capacitor.

Furthermore, the solid-state imaging device of the first aspect may further include a memory including a third electrode and a fourth electrode different from the third electrode, and the memory may include a second ferroelectric film between the third electrode and the fourth electrode in a case where the capacitor includes the first ferroelectric film, and includes a second antiferroelectric film between the third electrode and the fourth electrode in a case where the capacitor includes the first antiferroelectric film. As a result, for example, the total cost of the capacitor and the memory can be reduced by simultaneously forming the capacitor and the memory.

Furthermore, in the first aspect, the third electrode may be formed of the same material as the first electrode, the fourth electrode may be formed of the same material as the second electrode, and the second ferroelectric film or the second antiferroelectric film may be formed of the same material as the first ferroelectric film or the first antiferroelectric film. As a result, for example, the total cost of the capacitor and the memory can be reduced by forming the capacitor and the memory with the same material.

A solid-state imaging device of a second aspect of the present disclosure includes: a first substrate; a photoelectric conversion unit provided in the first substrate; a floating diffusion unit provided in the first substrate; a capacitor including a first electrode provided on a first surface side or a second surface side of the first substrate, a second electrode different from the first electrode, and a first ferroelectric film, a first antiferroelectric film, or a first paraelectric film provided between the first electrode and the second electrode; and a memory including a third electrode and a fourth electrode different from the third electrode, in which the memory includes a second ferroelectric film between the third electrode and the fourth electrode in a case where the capacitor includes the first ferroelectric film, includes a second antiferroelectric film between the third electrode and the fourth electrode in a case where the capacitor includes the first antiferroelectric film, and includes a second paraelectric film between the third electrode and the fourth electrode in a case where the capacitor includes the first paraelectric film. As a result, for example, the total cost of the capacitor and the memory can be reduced by simultaneously forming the capacitor and the memory, and the cost related to the capacitor can be reduced.

Furthermore, in the second aspect, the third electrode may be formed of the same material as the first electrode, the fourth electrode may be formed of the same material as the second electrode, and the second ferroelectric film, the second antiferroelectric film, or the second paraelectric film may be formed of the same material as the first ferroelectric film, the first antiferroelectric film, or the second paraelectric film. As a result, for example, the total cost of the capacitor and the memory can be reduced by forming the capacitor and the memory with the same material.

Furthermore, in the second aspect, the first and second ferroelectric films, the first and second antiferroelectric films, or the first and second paraelectric films may contain hafnium (Hf), zirconium (Zr), niobium (Nb), scandium (Sc), yttrium (Y), lanthanum (La), germanium (Ge), or silicon (Si). Thus, for example, a suitable ferroelectric film, antiferroelectric film, or paraelectric film can be formed.

Furthermore, in the second aspect, the capacitor and the memory may be provided on the first surface side of the first substrate, and the solid-state imaging device may further include a lens provided on the second surface side of the first substrate. As a result, for example, the capacitor and the memory can be applied to a back-illuminated type solid-state imaging device.

Furthermore, the solid-state imaging device of the second aspect may further include a pixel transistor electrically connected to the floating diffusion unit, and the first electrode may be electrically connected or connectable to the pixel transistor. As a result, for example, the cost related to the capacitor of the solid-state imaging device including such a pixel transistor can be reduced.

Furthermore, the solid-state imaging device of the second aspect may further include a second substrate bonded to the first substrate, and the pixel transistor, the capacitor, and the memory may be provided between the first substrate and the second substrate. As a result, for example, the capacitor and the memory can be applied to a solid-state imaging device configured using two substrates.

Furthermore, in the second aspect, the pixel transistor may be provided in a first insulating film provided on the first substrate, and the capacitor and the memory may be provided in a second insulating film provided on the second substrate and located between the second substrate and the first insulating film. As a result, for example, the capacitor and the memory can be applied to a solid-state imaging device configured using two substrates.

Furthermore, the solid-state imaging device of the second aspect may further include a third substrate provided between the first substrate and the second substrate, and the capacitor and the memory may be provided between the second substrate and the third substrate. As a result, for example, the capacitor and the memory can be applied to a solid-state imaging device configured using three substrates.

Furthermore, in the second aspect, the capacitor and the memory may have a portion provided in the same cross section. As a result, for example, the capacitor and the memory can be formed at substantially the same height at the same time.

### BRIEF DESCRIPTION OF DRAWINGS

FIG. 1 is a block diagram illustrating a configuration of a solid-state imaging device of a first embodiment.

FIG. 2 is a circuit diagram showing a configuration of the solid-state imaging device of the first embodiment.

FIG. 3 is a cross-sectional view illustrating a first example of a structure of the solid-state imaging device of the first embodiment.

FIG. 4 is a cross-sectional view illustrating a second example of the structure of the solid-state imaging device of the first embodiment.

FIG. 5 is a perspective view illustrating the structure of the solid-state imaging device illustrated in FIG. 4.

FIG. 6 is a graph for explaining the operation of the solid-state imaging device of the first embodiment.

FIG. 7 is a cross-sectional view illustrating a structure of a solid-state imaging device of a second embodiment.

FIG. 8 is a graph for explaining the operation of the solid-state imaging device of the second embodiment.

FIG. 9 is a cross-sectional view illustrating a structure of a solid-state imaging device of a third embodiment.

FIG. 10 is a graph for explaining the operation of the solid-state imaging device of the third embodiment.

FIG. 11 is a perspective view illustrating a structure of a solid-state imaging device of a fourth embodiment.

FIG. 12 is a perspective view illustrating a structure of a solid-state imaging device of a fifth embodiment.

FIG. 13 is a transverse cross-sectional view illustrating two examples of a structure of a solid-state imaging device of a sixth embodiment.

FIG. 14 is a perspective view illustrating a structure of a solid-state imaging device of a seventh embodiment.

FIG. 15 is a block diagram illustrating a configuration of the solid-state imaging device of the seventh embodiment.

FIG. 16 is a circuit diagram showing a configuration of a solid-state imaging device of an eighth embodiment.

FIG. 17 is a circuit diagram showing a configuration of a solid-state imaging device of a ninth embodiment.

FIG. 18 is a circuit diagram showing a configuration of a solid-state imaging device of a tenth embodiment.

FIG. 19 is a circuit diagram showing a configuration of a solid-state imaging device of an eleventh embodiment.

FIG. 20 is a block diagram illustrating a configuration example of an electronic device.

FIG. 21 is a block diagram illustrating a configuration example of a moving body control system.

FIG. 22 is a plan view illustrating a specific example of a setting position of an imaging unit in FIG. 21.

FIG. 23 is a view illustrating an example of a schematic configuration of an endoscopic surgery system.

FIG. 24 is a block diagram illustrating an example of a functional configuration of a camera head and a camera control unit (CCU).

### MODE FOR CARRYING OUT THE INVENTION

Hereinafter, embodiments of the present disclosure are described below with reference to the drawings.

### First Embodiment

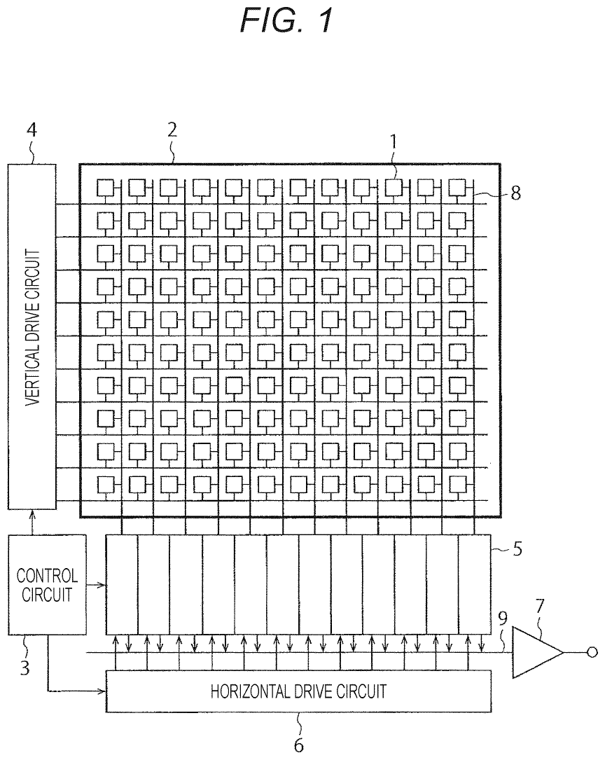

FIG. 1 is a block diagram illustrating a configuration of a solid-state imaging device of a first embodiment.

The solid-state imaging device in FIG. 1 is a complementary metal oxide semiconductor (CMOS) type image sensor (CIS), and includes a pixel array region 2 having a plurality of pixels 1, a control circuit 3, a vertical drive circuit 4, a plurality of column signal processing circuits 5, a horizontal drive circuit 6, an output circuit 7, a plurality of vertical signal lines (VSL) 8, and a horizontal signal line (HSL) 9.

Each of the pixels 1 includes a photodiode functioning as a photoelectric conversion unit and a MOS transistor functioning as a pixel transistor. Examples of the pixel transistor include a transfer transistor, a reset transistor, an amplifying transistor, a selection transistor, and a switch transistor. These pixel transistors may be shared by several pixels 1.

The pixel array region 2 includes a plurality of pixels 1 arranged in a two-dimensional array. The pixel array region 2 includes an effective pixel region that receives light, performs photoelectric conversion, and outputs a signal charge generated by the photoelectric conversion, and a black reference pixel region that outputs optical black serving as a reference of a black level. In general, the black reference pixel region is arranged on an outer peripheral portion of the effective pixel region.

The control circuit 3 generates various signals serving as references of operations of the vertical drive circuit 4, the column signal processing circuit 5, the horizontal drive circuit 6, and the like on the basis of a vertical synchronization signal, a horizontal synchronization signal, a master clock, and the like. The signals generated by the control circuit 3 are, for example, a clock signal and a control signal, and are input to the vertical drive circuit 4, the column signal processing circuit 5, the horizontal drive circuit 6, and the like.

The vertical drive circuit 4 includes, for example, a shift register, and scans each of the pixels 1 in the pixel array region 2 in the vertical direction row by row. The vertical drive circuit 4 further supplies a pixel signal based on the signal charge generated by each pixel 1 to the column signal processing circuit 5 through the vertical signal line 8.

The column signal processing circuit 5 is arranged, for example, for every column of the pixels 1 in the pixel array region 2, and performs signal processing of the signals output from the pixels 1 of one row for every column on the basis of a signal from the black reference pixel region. Examples of this signal processing are noise removal and signal amplification.

The horizontal drive circuit 6 includes, for example, a shift register, and supplies the pixel signal from each of the column signal processing circuits 5 to the horizontal signal line 9.

The output circuit 7 performs signal processing on the signal supplied from each of the column signal processing circuits 5 through the horizontal signal line 9, and outputs the signal subjected to the signal processing.

Note that the pixel array region 2 of the present embodiment may include only one of the pixel 1 that detects visible light and the pixel 1 that detects light other than visible light, or may include both the pixel 1 that detects visible light and the pixel 1 that detects light other than visible light. The light other than the visible light is, for example, infrared light.

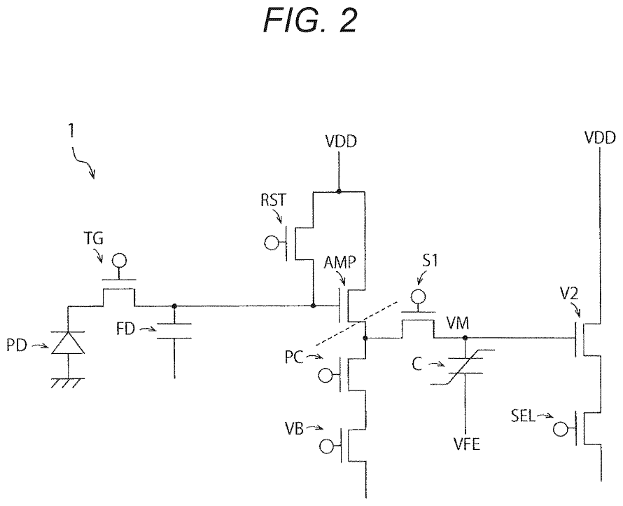

FIG. 2 is a circuit diagram illustrating a configuration of the solid-state imaging device of the first embodiment.

As illustrated in FIG. 2, each pixel 1 includes a photodiode PD, a floating diffusion unit FD, a ferroelectric capacitor C, a transfer transistor TG, a reset transistor RST, an amplifying transistor AMP, a selection transistor SEL, a switch transistor S1, a post-amplifying transistor V2, a current source transistor PC, and a post-current source transistor VB. The solid-state imaging device of the present embodiment is a voltage domain type CIS (VD-GS) that realizes a global shutter function by simultaneously converting charges generated in the photodiodes PD into voltages in all the pixels 1 and holding the voltages until reading is completed.

The photodiode PD performs photoelectric conversion of incident light. The anode of the photodiode PD is electrically connected to the ground potential, and the cathode of the photodiode PD is electrically connected to the transfer transistor TG. Incident light into the photodiode PD is referred to as exposure of the photodiode PD.

The transfer transistor TG transfers the charge generated by the photoelectric conversion to the floating diffusion unit FD. One of the source and the drain of the transfer transistor TG is electrically connected to the photodiode PD, and the other of the source and the drain of the transfer transistor TG is electrically connected to the floating diffusion unit FD, the reset transistor RST, and the amplifying transistor AMP.

The floating diffusion unit FD accumulates the charge transferred by the transfer transistor TG. As illustrated in FIG. 2, the floating diffusion unit FD functions as a capacitor. The floating diffusion unit FD is electrically connected to the transfer transistor TG, the reset transistor RST, and the amplifying transistor AMP.

The reset transistor RST discharges charges from the floating diffusion unit FD and resets the potential of the floating diffusion unit FD to the power supply voltage (VDD) before the exposure of the photodiode PD is started. One of the source and the drain of the reset transistor RST is electrically connected to the power supply voltage, and the other of the source and the drain of the reset transistor RST is electrically connected to the transfer transistor TG, the floating diffusion unit FD, and the amplifying transistor AMP.

The amplifying transistor AMP receives the charge transferred to the floating diffusion unit FD at the gate, and outputs the charge to the switch transistor S1 by the source follower. The gate of the amplifying transistor AMP is electrically connected to the transfer transistor TG, the floating diffusion unit FD, and the reset transistor RST. One of the source and the drain of the amplifying transistor AMP is electrically connected to the power supply voltage, and the other of the source and the drain of the amplifying transistor AMP is electrically connected to the switch transistor S1 and the current source transistor PC.

The switch transistor S1 can electrically connect the amplifying transistor AMP and the post-amplifying transistor V2. When the switch transistor S1 is turned on, the amplifying transistor AMP and the post-amplifying transistor V2 are electrically connected, and when the switch transistor S1 is turned off, the amplifying transistor AMP and the post-amplifying transistor V2 are electrically insulated. One of the source and the drain of the switch transistor S1 is electrically connected to the amplifying transistor AMP and the current source transistor PC, and the other of the source and the drain of the switch transistor S1 is electrically connected to the ferroelectric capacitor C and the post-amplifying transistor V2.

The post-amplifying transistor V2 receives the charge output from the amplifying transistor AMP at the gate, and outputs the charge to the vertical signal line 8 by the source follower. The gate of the post-amplifying transistor V2 is electrically connected to the switch transistor S1 and the ferroelectric capacitor C. One of the source and the drain of the post-amplifying transistor V2 is electrically connected to the power supply voltage, and the other of the source and the drain of the post-amplifying transistor V2 is electrically connected to the selection transistor SEL.

The selection transistor SEL can electrically connect the post-amplifying transistor V2 and the vertical signal line 8. When the selection transistor SEL is turned on, the post-amplifying transistor V2 and the vertical signal line 8 are electrically connected, and when the selection transistor SEL is turned off, the post-amplifying transistor V2 and the vertical signal line 8 are electrically insulated. One of the source and the drain of the selection transistor SEL is electrically connected to the post-amplifying transistor V2, and the other of the source and the drain of the selection transistor SEL is electrically connected to or connectable to the vertical signal line 8.

FIG. 2 illustrates a node VM between the switch transistor S1, the ferroelectric capacitor C, and the selection transistor SEL. The gate of the post-amplifying transistor V2 is electrically connected to the node VM, and the operation of the post-amplifying transistor V2 is controlled by the voltage of the node VM.

The current source transistor PC and the post-current source transistor VB function as current sources. One of the source and the drain of the current source transistor PC is electrically connected to the amplifying transistor AMP, and the other of the source and the drain of the current source transistor PC is electrically connected to the post-current source transistor VB. One of the source and the drain of the post-current source transistor VB is electrically connected to the current source transistor PC.

The ferroelectric capacitor C is electrically connected to the node VM. Specifically, one electrode of the ferroelectric capacitor C is electrically connected to the switch transistor S1 and the post-amplifying transistor V2, and electrically connectable to the amplifying transistor AMP and the current source transistor PC via the switch transistor S1, and corresponds to an example of the first electrode of the present disclosure. The other electrode of the ferroelectric capacitor C is electrically connected to the wiring that supplies a voltage VFE, and corresponds to an example of a second electrode of the present disclosure. The ferroelectric capacitor C includes a ferroelectric film between these electrodes. This ferroelectric film is an example of the first ferroelectric film of the present disclosure. The ferroelectric capacitor C illustrated in FIG. 2 is used to hold a signal of the pixel 1 illustrated in FIG. 2.

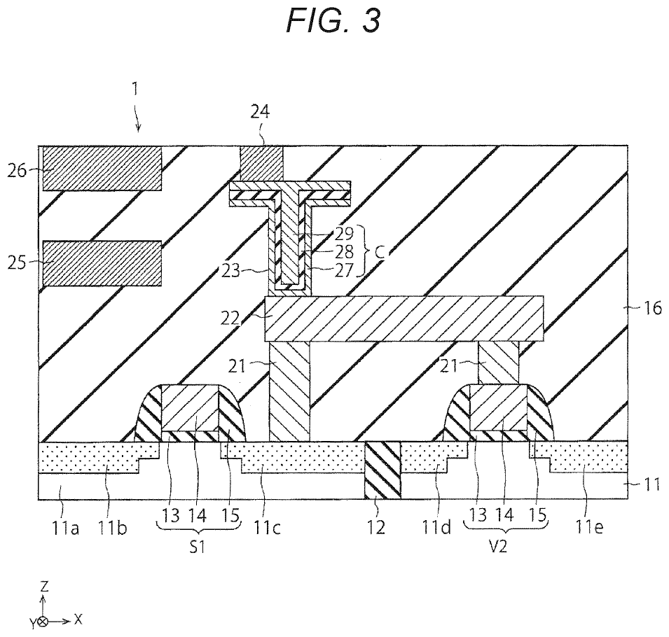

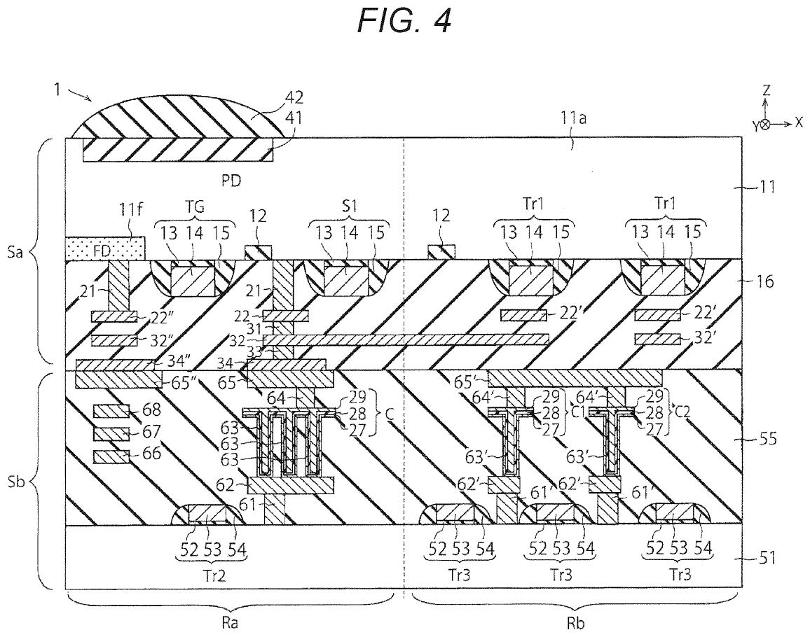

The solid-state imaging device of the present embodiment has, for example, a structure as illustrated in FIG. 3 or a structure as illustrated in FIG. 4. Hereinafter, two examples of the structure of the solid-state imaging device of the present embodiment will be described with reference to FIGS. 3 and 4 in order.

FIG. 3 is a cross-sectional view illustrating a first example of the structure of the solid-state imaging device of the first embodiment. Similarly to FIG. 2, FIG. 3 illustrates one pixel 1 in the solid-state imaging device of the present embodiment.

FIG. 3 illustrates an X axis, a Y axis, and a Z axis perpendicular to each other. An X direction and a Y direction correspond to a lateral direction (horizontal direction), and a Z direction corresponds to a longitudinal direction (vertical direction). Furthermore, a +Z direction corresponds to an upward direction, and a −Z direction corresponds to a downward direction. Note that the −Z direction may strictly match the gravity direction, or does not necessarily strictly match the gravity direction.

The solid-state imaging device illustrated in FIG. 3 includes a substrate 11, an element isolation insulating film 12, a gate insulating film 13, a gate electrode 14, and a sidewall insulating film 15 included in the switch transistor S1 and the post-amplifying transistor V2, and an interlayer insulating film 16. The substrate 11 is an example of a first substrate of the present disclosure, and the interlayer insulating film 16 is an example of a first insulating film of the present disclosure.

The solid-state imaging device illustrated in FIG. 3 further includes a plurality of contact plugs 21, a wiring 22, a contact hole 23, a wiring 24, a wiring 25, a wiring 26, and an electrode 27, a ferroelectric film 28, and an electrode 29 included in the ferroelectric capacitor C. The electrode 27, the ferroelectric film 28, and the electrode 29 are examples of the first electrode, the first ferroelectric film, and the second electrode of the present disclosure, respectively.

The substrate 11 is, for example, a semiconductor substrate such as a silicon substrate. In FIG. 3, the X direction and the Y direction are parallel to the upper surface of the substrate 11, and the Z direction is perpendicular to the upper surface of the substrate 11. The substrate 11 includes a well region 11a and diffusion regions 11b, 11c, 11d, and 11e. The diffusion regions 11b and 11c function as source and drain regions of the switch transistor S1, and the diffusion regions 11d and 11e function as source and drain regions of the post-amplifying transistor V2. The substrate 11 further includes the photodiode PD and the floating diffusion unit FD described with reference to FIG. 2 (not illustrated). The photodiode PD is formed by a pn junction in the substrate 11, and the floating diffusion unit FD is formed by a diffusion region in the substrate 11.

The element isolation insulating film 12 is formed in the substrate 11. The element isolation insulating film 12 is, for example, a silicon oxide film. The element isolation insulating film 12 illustrated in FIG. 3 is interposed between the switch transistor S1 and the post-amplifying transistor V2.

In each of the switch transistor S1 and the post-amplifying transistor V2, the gate insulating film 13 is formed on the substrate 11, the gate electrode 14 is formed on the gate insulating film 13, and the sidewall insulating film 15 is formed on the side surface of the gate electrode 14. In the example illustrated in FIG. 3, each of the transfer transistor TG, the reset transistor RST, the amplifying transistor AMP, the selection transistor SEL, the current source transistor PC, and the post-current source transistor VB also includes a gate insulating film 13, a gate electrode 14, and a sidewall insulating film 15.

The interlayer insulating film 16 is formed on the substrate 11 so as to cover the switch transistor S1 and the post-amplifying transistor V2. In the example illustrated in FIG. 3, the transfer transistor TG, the reset transistor RST, the amplifying transistor AMP, the selection transistor SEL, the current source transistor PC, the post-current source transistor VB, and the like are also covered with the interlayer insulating film 26.

The contact plug 21, the wiring 22, the contact hole 23, and the wiring 24 are formed in the interlayer insulating film 16 on the substrate 11. FIG. 3 illustrates the contact plug 21 provided on the diffusion region 11c of the switch transistor S1 and the contact plug 21 provided on the gate electrode 14 of the post-amplifying transistor V2. The wiring 22 is provided on these contact plugs 21, and electrically connects the switch transistor S1 and the post-amplifying transistor V2. Note that the above-described node VM is located, for example, in the wiring 22.

The contact hole 23 is provided on the wiring 22. A part of the ferroelectric capacitor C is embedded in the contact hole 23 and is electrically connected to the wiring 22 in the contact hole 23. The wiring 24 is provided on the ferroelectric capacitor C and is electrically connected to the ferroelectric capacitor C. Note that the wiring 24 is electrically connected to the wiring that supplies the above-described voltage VFE.

The wirings 25 and 26 are also formed in the interlayer insulating film 16 on the substrate 11. The wiring 25 is provided at the same height as a part of the contact hole 23. The wiring 26 is provided at the same height as the wiring 24.

The ferroelectric capacitor C includes an electrode 27, a ferroelectric film 28, and an electrode 29 which are sequentially formed inside and outside the contact hole 23. Inside the contact hole 23, the electrode 27, the ferroelectric film 28, and the electrode 29 are sequentially formed on the upper surface of the wiring 22 and the side surface of the interlayer insulating film 16. Outside the contact hole 23, the electrode 27, the ferroelectric film 28, and the electrode 29 are sequentially formed on the upper surface of the interlayer insulating film 16. The electrode 27 is in contact with the upper surface of the wiring 22 and is electrically connected to the wiring 22. The electrode 29 is in contact with the lower surface of the wiring 24 and is electrically connected to the wiring 24. As described above, the ferroelectric capacitor C in FIG. 3 has a three-dimensional structure spreading in the X direction, the Y direction, and the Z direction.

The ferroelectric film 28 desirably contains, for example, hafnium (Hf), zirconium (Zr), niobium (Nb), scandium (Sc), yttrium (Y), lanthanum (La), germanium (Ge), or silicon (Si). Examples of the ferroelectric film 28 in FIG. 3 include a hafnium oxide (HfO₂) film, a lead zirconate titanate (PZT) film, a strontium bismuth tantalate (SBT) film, and a lanthanum bismuth titanate (BLT) film. On the other hand, each of the electrodes 27 and 29 is desirably formed of a metal having high reducibility, such as a laminated film including a TiN film and a TiAl film, or a laminated film including a TiN film, a TaN film, and a TiAl film (Ti, N, Al, and Ta represent titanium, nitrogen, aluminum, and tantalum, respectively.).

Note that the wiring 12 is located in the first (lowermost) wiring layer on the substrate 11. The ferroelectric capacitor C may be formed on the wiring in any one of the second or more wiring layers instead of being formed on the wiring 12 in the first wiring layer.

The solid-state imaging device of the present embodiment may have the structure illustrated in FIG. 4 instead of having the structure illustrated in FIG. 3. FIG. 3 illustrates a structure of a front-illuminated type solid-state imaging device, and FIG. 4 illustrates a structure of a back-illuminated type solid-state imaging device. When the back surface irradiation type structure is adopted, the area of the photodiode (PD) region can be effectively used, and the region where the ferroelectric capacitor C can be formed can be increased.

FIG. 4 is a cross-sectional view illustrating a second example of the structure of the solid-state imaging device of the first embodiment. Similarly to FIGS. 2 and 3, FIG. 4 illustrates one pixel 1 and the like in the solid-state imaging device of the present embodiment. The structure illustrated in FIG. 4 will be described focusing on differences from the structure illustrated in FIG. 3.

In FIG. 4, the lower surface of the substrate 11 is the front surface of the substrate 11, and the upper surface of the substrate 11 is the back surface of the substrate 11. The solid-state imaging device illustrated in FIG. 4 is a back-illuminated type, and an upper surface (back surface) of the substrate 11 is a light incident surface (light-receiving surface) of the substrate 11. In FIG. 4, the lower surface of the substrate 11 is an example of a first surface of the present disclosure, and the upper surface of the substrate 11 is an example of a second surface of the present disclosure.

The solid-state imaging device illustrated in FIG. 4 includes a region Ra including the above-described pixel array region 2 and the like and a region Rb including a logic circuit and the like as regions existing in the substrate 11, on the substrate 11, and under the substrate 11. In addition, the solid-state imaging device illustrated in FIG. 4 has a two-layer structure including an upper layer Sa and a lower layer Sb.

The upper layer Sa includes the substrate 11, the element isolation insulating film 12, the gate insulating film 13, the gate electrode 14, and the sidewall insulating film 15 included in the transfer transistor TG, the switch transistor S1, a transistor Tr1, and the like, the interlayer insulating film 16, the plurality of contact plugs 21, the wiring 22, a plurality of wirings 22′, and a wiring 22′. The upper layer Sa further includes a via plug 31, a wiring 32, a wiring 32′, a wiring 32″, a via plug 33, a wiring 34, and a wiring 34″, an on-chip filter 41, and an on-chip lens 42.

The lower layer Sb includes a substrate 51, a gate insulating film 52, a gate electrode 53, and a sidewall insulating film 54 included in a transistor Tr2, a transistor Tr3, and the like, and an interlayer insulating film 55. The lower layer Sb further includes a contact plug 61, a plurality of contact plugs 61′, a wiring 62, a plurality of wirings 62′, a plurality of contact holes 63, a plurality of contact holes 63′, a wiring 64, a plurality of wirings 64′, a wiring 65, a wiring 65′, a wiring 65″, a wiring 66, a wiring 67, and a wiring 68. The lower layer Sb further includes an electrode 27, a ferroelectric film 28, and an electrode 29 included in a ferroelectric capacitor C and memory capacitors C1 and C2. The substrate 51 is an example of a second substrate of the present disclosure, and the interlayer insulating film 55 is an example of a second insulating film of the present disclosure.

### [Upper Layer Sa]

The substrate 11 illustrated in FIG. 4 includes the photodiode PD and the floating diffusion unit FD in the region Ra. The photodiode PD is formed by a pn junction in the substrate 11, and the floating diffusion unit FD is formed by a diffusion region 11f in the substrate 11.

The on-chip filter 41 and the on-chip lens 42 are arranged on the upper surface side of the substrate 11 in the region Ra. Specifically, the on-chip filter 41 is formed on the upper surface of the substrate 11, and the on-chip lens 42 is formed on the on-chip filter 41.

The on-chip filter 41 has a function of transmitting light having a predetermined wavelength, and is formed on the upper surface of the substrate 11 for each pixel 1. For example, the on-chip filters 41 for red (R), green (G), and blue (B) are arranged above the photodiodes PD of the red, green, and blue pixels 1, respectively. Furthermore, the on-chip filter 41 for infrared light may be arranged above the photodiode PD of the pixel 1 of infrared light.

The on-chip lens 42 has a function of condensing incident light, and is formed on the on-chip filter 41 for each pixel 1. In the present embodiment, light incident on the on-chip lens 42 is condensed by the on-chip lens 42, transmitted through the on-chip filter 41, and incident on the photodiode PD. The photodiode PD converts the light into a charge by photoelectric conversion to generate a signal charge.

On the other hand, the other components in the upper layer Sa are disposed on the lower surface side of the substrate 11. The transfer transistor TG, the switch transistor S1, and other pixel transistors are provided on the lower surface of the substrate 11 in the region Ra, and the transistor Tr1 is provided on the lower surface of the substrate 11 in the region Rb. These transistors are covered with the interlayer insulating film 16. The transistor Tr1 constitutes, for example, a logic circuit in the region Rb. Note that the ferroelectric capacitor C and the memory capacitors C1 and C2 are disposed on the lower surface side of the substrate 11, but are disposed not in the upper layer Sa but in the lower layer Sb. Furthermore, some pixel transistors may be arranged not in the region Ra of the upper layer Sa but in the region Ra of the lower layer Sb.

In the region Ra, the contact plug 21, the wiring 22, the via plug 31, the wiring 32, the via plug 33, and the wiring 34 are sequentially provided on the lower surface of the substrate 11. Further, in the region Ra, the contact plug 21, the wiring 22″, the wiring 32″, and the wiring 34″ are sequentially provided on the lower surface of the substrate 11. On the other hand, in the region Rb, a part of the wiring 32 and the wiring 32′ are provided below the substrate 11 via the wiring 22′.

### [Lower Layer Sb]

The substrate 51 is, for example, a semiconductor substrate such as a silicon substrate. The transistor Tr2 is provided on the substrate 51 in the region Ra, and the transistor Tr3 is provided on the substrate 51 in the region Rb. The transistor Tr2 constitutes a sample hold circuit together with the ferroelectric capacitor C in the region Ra, for example. The transistor Tr3 constitutes a frame memory together with the memory capacitors C1 and C2 in the region Rb, for example. These transistors are covered with an interlayer insulating film 55 formed on the substrate 51. The interlayer insulating film 55 has a lower surface in contact with the substrate 51 and an upper surface in contact with the interlayer insulating film 16, and is located between the substrate 51 and the interlayer insulating film 16. In FIG. 4, the substrate 51 is bonded to the substrate 11 via the interlayer insulating films 55 and 16. Note that the shape and arrangement of the gate insulating film 52, the gate electrode 53, and the sidewall insulating film 54 are similar to the shape and arrangement of the gate insulating film 13, the gate electrode 14, and the sidewall insulating film 15, respectively.

The contact plug 61, the wiring 62, the contact hole 63, the wiring 64, and the wiring 65 are formed in the interlayer insulating film 55 on the substrate 51 in the region Ra. The contact plug 61 is provided on the substrate 51. The wiring 62 is provided on the contact plug 61. The contact hole 63 is provided on the wiring 62. A part of the ferroelectric capacitor C is embedded in the contact hole 63 and is electrically connected to the wiring 62 in the contact hole 63. The wiring 64 is provided on the ferroelectric capacitor C and is electrically connected to the ferroelectric capacitor C. The wiring 65 is provided on the wiring 64 and is in contact with the wiring 34. The wiring 65″ is provided at the same height as the wiring 65 and is in contact with the wiring 34″. The wirings 66, 67, and 68 are provided at the same height as a part of the contact hole 63.

The ferroelectric capacitor C illustrated in FIG. 4 includes the electrode 27, the ferroelectric film 28, and the electrode 29 which are sequentially formed inside and outside the contact hole 63. Inside the contact hole 63, the electrode 27, the ferroelectric film 28, and the electrode 29 are sequentially formed on the upper surface of the wiring 62 and the side surface of the interlayer insulating film 55. Outside the contact hole 63, the electrode 27, the ferroelectric film 28, and the electrode 29 are sequentially formed on the upper surface of the interlayer insulating film 55. The electrode 27 is in contact with the upper surface of the wiring 62 and is electrically connected to the wiring 62. Similarly, the electrode 29 is in contact with the lower surface of the wiring 64 and is electrically connected to the wiring 64. As described above, the ferroelectric capacitor C illustrated in FIG. 4 has a three-dimensional structure spreading in the X direction, the Y direction, and the Z direction.

The ferroelectric capacitor C illustrated in FIG. 4 includes a plurality of partial capacitors formed in the plurality of contact holes 63, and these partial capacitors are connected in parallel. Note that the contact area between these partial capacitors and the wiring 62 is desirably as wide as possible.

The contact plug 61′, the wiring 62′, the contact hole 63′, the wiring 64′, and the wiring 65′ are formed in the interlayer insulating film 55 on the substrate 51 in the region Rb. The contact plug 61′ is provided on the substrate 51. The wiring 62′ is provided on the contact plug 61′. The contact hole 63′ is provided on the wiring 62′. A part of the memory capacitors C1 and C2 is embedded in the contact hole 63′ and is electrically connected to the wiring 62′ in the contact hole 63′. The wiring 64′ is provided on the memory capacitors C1 and C2, and is electrically connected to the memory capacitors C1 and C2. The wiring 65′ is provided on the wiring 64′.

Each of the memory capacitors C1 and C2 includes the electrode 27, the ferroelectric film 28, and the electrode 29 which are sequentially formed inside and outside the contact hole 63′. Inside the contact hole 63′, the electrode 27, the ferroelectric film 28, and the electrode 29 are sequentially formed on the upper surface of the wiring 62′ and the side surface of the interlayer insulating film 55. Outside the contact hole 63′, the electrode 27, the ferroelectric film 28, and the electrode 29 are sequentially formed on the upper surface of the interlayer insulating film 55. The electrode 27 is in contact with the upper surface of the wiring 62′ and is electrically connected to the wiring 62′. Similarly, the electrode 29 is in contact with the lower surface of the wiring 64′ and is electrically connected to the wiring 64′. As described above, the memory capacitors C1 and C2 have a three-dimensional structure spreading in the X direction, the Y direction, and the Z direction. The electrode 27, the ferroelectric film 28, and the electrode 29 of the memory capacitors C1 and C2 are examples of a third electrode, a second ferroelectric film, and a fourth electrode of the present disclosure, respectively.

In FIG. 4, a plurality of memory capacitors C1 and C2 are formed in the plurality of contact holes 63′. These memory capacitors C1 and C2 are disposed on different wirings 62′ and under different wirings 64′, but are electrically connected to the same wiring 65′.

Next, further details of the ferroelectric capacitor C and the memory capacitors C1 and C2 of the present embodiment will be described.

In the solid-state imaging device of the present embodiment, the electrodes 27 of the memory capacitors C1 and C2 are formed of the same material as the electrode 27 of the ferroelectric capacitor C, the ferroelectric films 28 of the memory capacitors C1 and C2 are formed of the same material as the ferroelectric film 28 of the ferroelectric capacitor C, and the electrodes 29 of the memory capacitors C1 and C2 are formed of the same material as the electrode 29 of the ferroelectric capacitor C.

Therefore, the electrodes 27, the ferroelectric films 28, and the electrodes 29 of the memory capacitors C1 and C2 have the same composition as the electrodes 27, the ferroelectric films 28, and the electrodes 29 of the ferroelectric capacitors C, respectively. For example, in a case where the ferroelectric film 28 of the ferroelectric capacitor C is a PZT film, the ferroelectric films 28 of the memory capacitors C1 and C2 are also PZT films. However, in a case where the composition of at least one of these ferroelectric films 28 is changed after formation of these ferroelectric films 28, these ferroelectric films 28 may not have the same composition.

Further, the electrodes 27, the ferroelectric films 28, and the electrodes 29 of the memory capacitors C1 and C2 have the same film thicknesses as the electrodes 27, the ferroelectric films 28, and the electrodes 29 of the ferroelectric capacitors C, respectively. For example, in a case where the film thickness of the ferroelectric film 28 of the ferroelectric capacitor C is X nm, the ferroelectric films 28 of the memory capacitors C1 and C2 are also X nm (X is an arbitrary real number). However, in a case where the film thickness of at least one of these ferroelectric films 28 is changed after formation of these ferroelectric films 28, these ferroelectric films 28 may not have the same film thickness.

In the solid-state imaging device of the present embodiment, since the memory capacitors C1 and C2 and the ferroelectric capacitor C are formed of the same material, not only the ferroelectric capacitor C but also the memory capacitors C1 and C2 are ferroelectric capacitors. Note that at least one of the electrode 27 and the electrode 29 may be made of a material different between the memory capacitors C1 and C2 and the ferroelectric capacitor C.

The ferroelectric capacitor C and the memory capacitors C1 and C2 of the present embodiment are formed, for example, as follows. First, the contact holes 63 and 63′ are simultaneously formed in the interlayer insulating film 55. Next, a lower electrode material, a ferroelectric material, and an upper electrode material are sequentially formed inside and outside the contact holes 63 and 63′. Next, the lower electrode material, the ferroelectric material, and the upper electrode material are processed by etching. As a result, the electrodes 27, the ferroelectric films 28, and the electrodes 29 of the ferroelectric capacitor C and the memory capacitors C1 and C2 are formed from the lower electrode material, the ferroelectric material, and the upper electrode material, respectively.

In FIG. 4, the height (Z coordinate) of the lower end of the contact hole 63′ is substantially the same as the height of the lower end of the contact hole 63, and the height of the upper end of the contact hole 63′ is also substantially the same as the height of the upper end of the contact hole 63. Therefore, the ferroelectric capacitor C and the memory capacitors C1 and C2 can be cut at the same XY cross section (cross section). That is, in the solid-state imaging device illustrated in FIG. 4, an XY plane passing through both the ferroelectric capacitor C and the memory capacitors C1 and C2 can be set. This can be expressed that the ferroelectric capacitor C and the memory capacitors C1 and C2 are located at the same height. Note that the heights of the lower ends of the contact holes 63 and 63′ may not coincide with each other, and the heights of the upper ends of the contact holes 63 and 63′ may not coincide with each other. However, it is desirable to form the contact holes 63 and 63′ simultaneously in order to simplify the semiconductor manufacturing process, and in this case, the heights of the lower ends coincide with each other and the heights of the upper ends coincide with each other in many cases.

As described above, the solid-state imaging device of the present embodiment includes the ferroelectric capacitor C as a capacitor. As a result, it is possible to reduce the cost related to the capacitor, for example, it is possible to form a large-capacity capacitor or a high-performance capacitor at low cost.

Furthermore, the solid-state imaging device of the present embodiment includes the ferroelectric capacitor C as a capacitor, and includes the memory capacitors C1 and C2 as ferroelectric capacitors. As a result, the ferroelectric capacitor C and the memory capacitors C1 and C2 can be formed at the same time, the ferroelectric capacitor C and the memory capacitors C1 and C2 can be formed of the same material, and the total cost of the ferroelectric capacitor C and the memory capacitors C1 and C2 can be reduced. Furthermore, in the present embodiment, since the frame memory is an FeRAM, the capacity and performance of the frame memory can be improved.

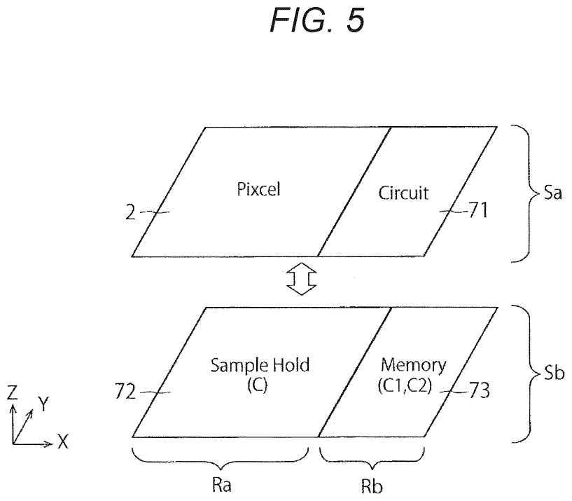

FIG. 5 is a perspective view illustrating a structure of the solid-state imaging device illustrated in FIG. 4.

FIG. 5 schematically illustrates a relationship between the upper layer Sa and the lower layer Sb. In FIG. 5, the upper layer Sa includes the pixel array region 2 provided in the region Ra and the circuit region 71 provided in the region Rb, and the lower layer Sb includes the sample hold region 72 provided in the region Ra and the memory region 73 provided in the region Rb.

The pixel array region 2 includes the plurality of pixels 1 (see FIG. 1). The circuit region 71 includes a logic circuit including the transistor Tr1 and the like. The sample hold region 72 includes a sample hold circuit including the transistor Tr2, the ferroelectric capacitor C, and the like. The memory region 73 includes a frame memory including the transistor Tr3, the memory capacitors C1 and C2, and the like.

In FIG. 5, since the upper layer Sa of the solid-state imaging device and the lower layer Sb of the solid-state imaging device are manufactured by different processes, the ferroelectric capacitors C and the memory capacitors C1 and C2 can be formed without being limited to the process generation of the upper layer Sa. For example, by manufacturing the ferroelectric capacitor C and the memory capacitors C1 and C2 by a finer technology, the capacity of the ferroelectric capacitor C and the memory capacitors C1 and C2 can be increased.

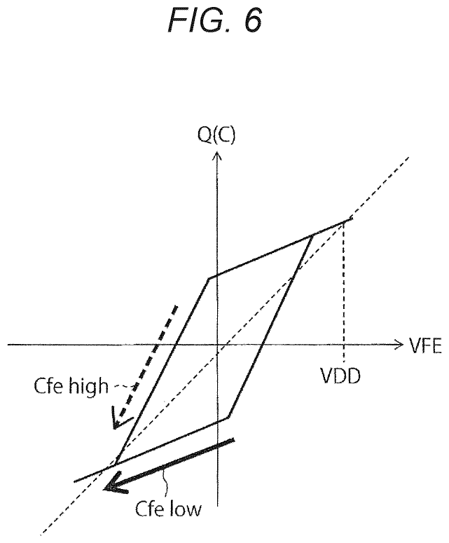

FIG. 6 is a graph for explaining the operation of the solid-state imaging device of the first embodiment.

FIG. 6 shows a Q-V curve for explaining the operation of the ferroelectric capacitor C of the present embodiment. The horizontal axis in FIG. 6 represents the potential (voltage VFE) applied to the ferroelectric capacitor C. The vertical axis in FIG. 6 represents the polarization amount generated in the ferroelectric capacitor C. When the direction of the write voltage applied to the ferroelectric capacitor C changes, residual polarization occurs in the ferroelectric capacitor C. Therefore, the Q-V curve of the ferroelectric capacitor C draws hysteresis as illustrated in FIG. 6. In addition, the capacity Cfe of the ferroelectric capacitor C represented by the slope of the Q-V curve can take two types of values of Cfe low and Cfe high as illustrated in FIG. 6. The Q-V curve shown in FIG. 6 has a shape close to a parallelogram. Cfe low corresponds to the inclination of the lower side of the parallelogram, and Cfe high corresponds to the inclination of the left side of the parallelogram.

In the solid-state imaging device of the present embodiment, before reading from the floating diffusion unit FD, the state of the ferroelectric capacitor C is set in advance to the “Cfe low state” instead of the “Cfe high state”. That is, before reading from the floating diffusion unit FD, the capacity Cfe of the ferroelectric capacitor C is not Cfe high but Cfe low. The state of the ferroelectric capacitor C is controlled by, for example, the control circuit 3.

The solid-state imaging device of the present embodiment is the VD-GS as described above. In this case, if the state of the ferroelectric capacitor C is set to the “Cfe high state” in advance before reading from the floating diffusion unit FD, the Cfe high state is destroyed at the time of reading. Therefore, in the present embodiment, only the Cfe low state is used. This corresponds to using the ferroelectric capacitor C like a paraelectric capacitor. The Cfe low state can be realized, for example, by setting the voltage VFE to 0 V and setting the voltage of the node VM to VDD.

As described above, the solid-state imaging device of the present embodiment includes the ferroelectric capacitor C as a capacitor, and includes the memory capacitors C1 and C2 as ferroelectric capacitors. Therefore, according to the present embodiment, the cost of the former capacitor (ferroelectric capacitor C) can be reduced, and the total cost of the ferroelectric capacitor C and the memory capacitors C1 and C2 can be reduced.

### Second Embodiment

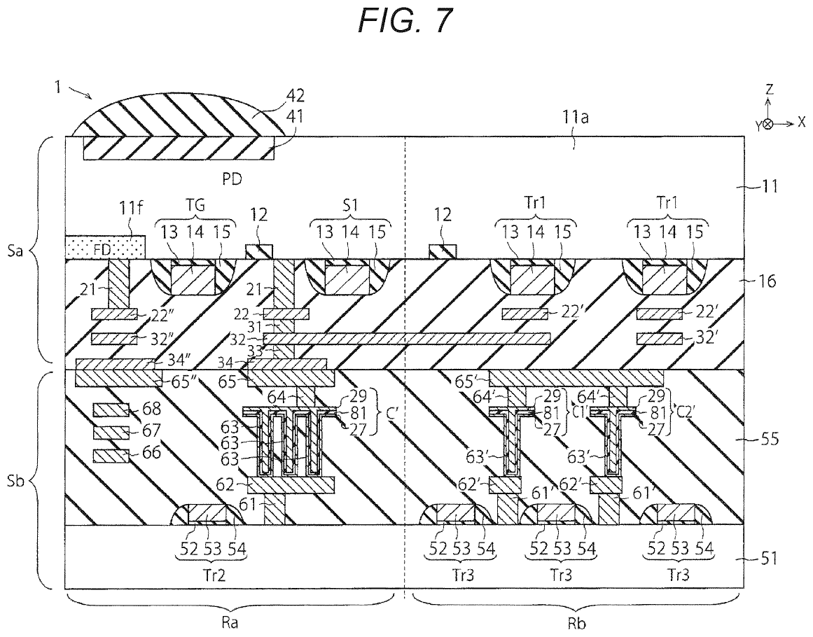

FIG. 7 is a cross-sectional view illustrating a structure of a solid-state imaging device of a second embodiment. Similarly to FIG. 4, FIG. 7 illustrates one pixel 1 and the like in the solid-state imaging device of the present embodiment. The structure illustrated in FIG. 7 will be described focusing on differences from the structure illustrated in FIG. 4.

The solid-state imaging device of the present embodiment has a structure in which the ferroelectric capacitor C is replaced with an antiferroelectric capacitor C′, and the memory capacitors C1 and C2 are replaced with memory capacitors C1′ and C2′. The antiferroelectric capacitor C′ includes an antiferroelectric film 81 instead of the ferroelectric film 28. The antiferroelectric film 81 is an example of a first antiferroelectric film of the present disclosure. Similarly, the memory capacitors C1′ and C2′ include the antiferroelectric film 81 instead of the ferroelectric film 28. The antiferroelectric film 81 is an example of a second antiferroelectric film of the present disclosure. In the present embodiment, not only the antiferroelectric capacitor C′ but also the memory capacitors C1′ and C2′ are antiferroelectric capacitors.

In the solid-state imaging device of the present embodiment, the electrodes 27 of the memory capacitors C1′ and C2′ are formed of the same material as the electrode 27 of the antiferroelectric capacitor C′, the antiferroelectric films 81 of the memory capacitors C1′ and C2′ are formed of the same material as the antiferroelectric film 81 of the antiferroelectric capacitor C′, and the electrodes 29 of the memory capacitors C1′ and C2′ are formed of the same material as the electrode 29 of the antiferroelectric capacitor C′. These antiferroelectric films 81 desirably contain, for example, hafnium (Hf), zirconium (Zr), niobium (Nb), scandium (Sc), yttrium (Y), lanthanum (La), germanium (Ge), or silicon (Si).

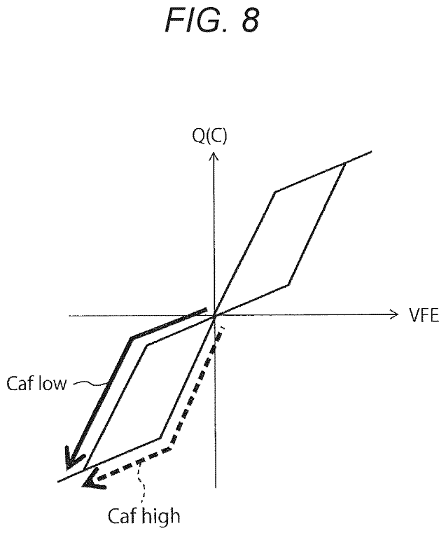

FIG. 8 is a graph for explaining the operation of the solid-state imaging device of the second embodiment.

FIG. 8 shows a Q-V curve for explaining the operation of the antiferroelectric capacitor C′ of the present embodiment. The Q-V curve of the antiferroelectric capacitor C′ draws hysteresis as illustrated in FIG. 8. FIG. 8 further shows Cfe low and Cfe high as values of the capacity Cfe of the antiferroelectric capacitor C′. In the solid-state imaging device of the present embodiment, before reading from the floating diffusion unit FD, the state of the antiferroelectric capacitor C′ is set in advance not to the “Caf high state” but to the “Caf low state”. The state of the antiferroelectric capacitor C′ is controlled by, for example, the control circuit 3.

As described above, the solid-state imaging device of the present embodiment includes the antiferroelectric capacitor C′ as a capacitor, and includes the memory capacitors C1′ and C2′ as antiferroelectric capacitors. Therefore, according to the present embodiment, the cost of the former capacitor (antiferroelectric capacitor C′) can be reduced, and the total cost of the antiferroelectric capacitor C′ and the memory capacitors C1′ and C2′ can be reduced. The frame memory of the present embodiment is an FeRAM because the memory capacitors C1′ and C2′ are antiferroelectric capacitors.

### Third Embodiment

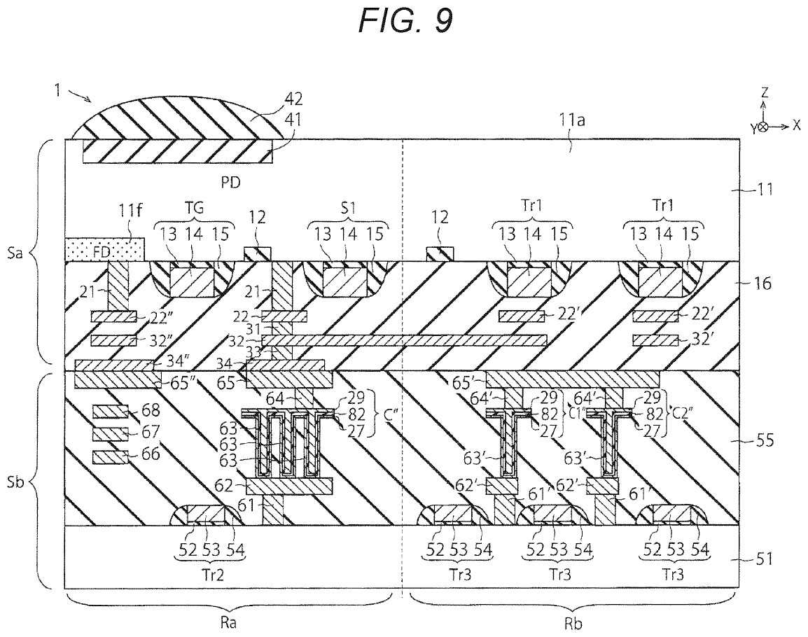

FIG. 9 is a cross-sectional view illustrating a structure of a solid-state imaging device of a third embodiment. Similarly to FIG. 4, FIG. 9 illustrates one pixel 1 and the like in the solid-state imaging device of the present embodiment. The structure illustrated in FIG. 9 will be described focusing on differences from the structure illustrated in FIG. 4.

The solid-state imaging device of the present embodiment has a structure in which the ferroelectric capacitor C is replaced with a paraelectric capacitor C″, and the memory capacitors C1 and C2 are replaced with memory capacitors C1″ and C2″. The paraelectric capacitor C″ includes a paraelectric film 82 instead of the ferroelectric film 28. The paraelectric film 82 is an example of a first paraelectric film of the present disclosure. Similarly, the memory capacitors C1″ and C2″ include the paraelectric film 82 instead of the ferroelectric film 28. The paraelectric film 82 is an example of a second paraelectric film of the present disclosure. In the present embodiment, not only the paraelectric capacitor C″ but also the memory capacitors C1″ and C2″ are antiferroelectric capacitors.

In the solid-state imaging device of the present embodiment, the electrodes 27 of the memory capacitors C1″ and C2″ are formed of the same material as the electrode 27 of the paraelectric capacitor C″, the paraelectric films 82 of the memory capacitors C1″ and C2″ are formed of the same material as the paraelectric film 82 of the paraelectric capacitor C″, and the electrodes 29 of the memory capacitors C1″ and C2″ are formed of the same material as the electrode 29 of the paraelectric capacitor C″. These paraelectric films 82 desirably contain, for example, hafnium (Hf), zirconium (Zr), niobium (Nb), scandium (Sc), yttrium (Y), lanthanum (La), germanium (Ge), or silicon (Si).

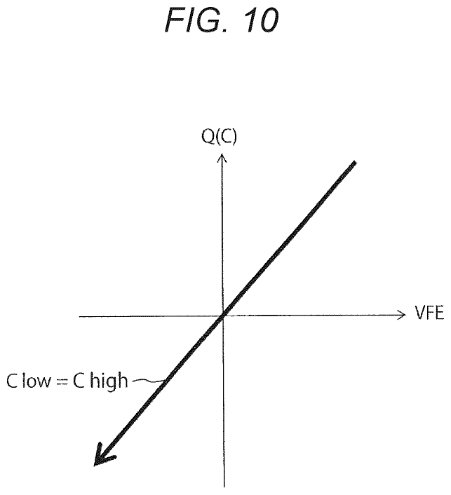

FIG. 10 is a graph for explaining the operation of the solid-state imaging device of the third embodiment.

FIG. 10 shows a Q-V curve for explaining the operation of the paraelectric capacitor C″ of the present embodiment. As shown in FIG. 10, the Q-V curve of the paraelectric capacitor C″ does not draw hysteresis. Therefore, the paraelectric capacitor C″ of the present embodiment does not have a plurality of values as the value of the capacity C, unlike the ferroelectric capacitor C of the first embodiment and the antiferroelectric capacitor C′ of the second embodiment. Before reading in the present embodiment, it is desirable to set the state of the paraelectric capacitor C″ to the “Clow state” in advance. This state may be the “C high state” or the “C low state”.

As described above, the solid-state imaging device of the present embodiment includes the paraelectric capacitor C″ as a capacitor, and includes the memory capacitors C1″ and C2″ as paraelectric capacitors. Therefore, according to the present embodiment, the total cost of the paraelectric capacitor C″ and the memory capacitors C1″ and C2″ can be reduced. The frame memory of the present embodiment is a DRAM since the memory capacitors C1″ and C2″ are paraelectric capacitors.

### Fourth Embodiment

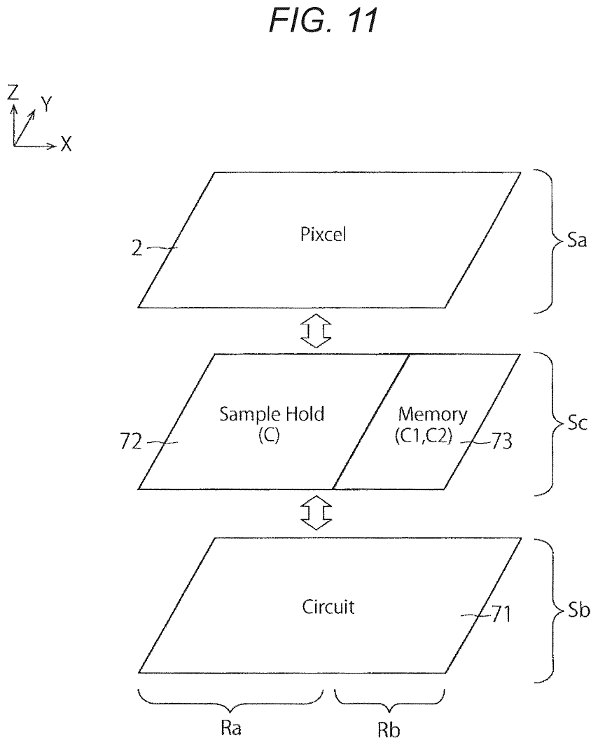

FIG. 11 is a perspective view illustrating a structure of a solid-state imaging device of a fourth embodiment.

The solid-state imaging device of the present embodiment has a structure illustrated in FIG. 11 instead of the structure illustrated in FIG. 5. The solid-state imaging device of the present embodiment has a three-layer structure including an upper layer Sa, a lower layer Sb, and an intermediate layer Sc. In the present embodiment, the upper layer Sa includes the pixel array region 2 provided in the regions Ra and Rb, the lower layer Sb includes the circuit region 71 provided in the regions Ra and Rb, and the intermediate layer Sc includes the sample hold region 72 provided in the region Ra and the memory region 73 provided in the region Rb.

The intermediate layer Sc includes, for example, a substrate similar to the substrates 11 and 51 (hereinafter referred to as “intermediate substrate”). In this case, the intermediate layer Sc includes, for example, the ferroelectric capacitor C, the memory capacitors C1 and C2, and the transistors Tr2 and Tr3 provided on the lower surface of the intermediate substrate, and an interlayer insulating film provided on the lower surface of the intermediate substrate so as to cover these transistors. The intermediate substrate is, for example, a semiconductor substrate such as a silicon substrate. The intermediate substrate is an example of a third substrate of the present disclosure.

In the present embodiment, since the upper layer Sa, the lower layer Sb, and the intermediate layer Sc of the solid-state imaging device are manufactured by different processes, it is possible to form the ferroelectric capacitor C and the memory capacitors C1 and C2 without being limited to the process generation of the upper layer Sa. For example, by manufacturing the ferroelectric capacitor C and the memory capacitors C1 and C2 by a finer technology, the capacity of the ferroelectric capacitor C and the memory capacitors C1 and C2 can be increased.

Note that the solid-state imaging device of the present embodiment may include the antiferroelectric capacitor C′ or the paraelectric capacitor C″ instead of the ferroelectric capacitor C, and may include the memory capacitors C1′ and C2′ or the memory capacitors C1″ and C2″ instead of the memory capacitors C1 and C2.

### Fifth Embodiment

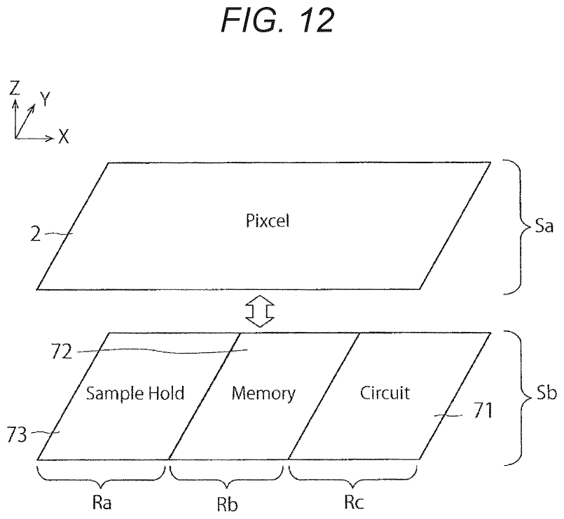

FIG. 12 is a perspective view illustrating a structure of a solid-state imaging device of a fifth embodiment.

The solid-state imaging device of the present embodiment has a structure illustrated in FIG. 12 instead of the structure illustrated in FIG. 5. The solid-state imaging device of the present embodiment includes a region Rc in addition to the regions Ra and Rb. The solid-state imaging device of the present embodiment further has a two-layer structure including the upper layer Sa and the lower layer Sb. In the present embodiment, the upper layer Sa includes the pixel array region 2 provided in the regions Ra, Rb, and Rc, and the lower layer Sb includes the circuit region 71 provided in the region Rc, the sample hold region 72 provided in the region Ra, and the memory region 73 provided in the region Rb.

In the present embodiment, since the upper layer Sa and the lower layer Sb of the solid-state imaging device are manufactured by different processes, the ferroelectric capacitor C and the memory capacitors C1 and C2 can be formed without being limited to the process generation of the upper layer Sa. For example, by manufacturing the ferroelectric capacitor C and the memory capacitors C1 and C2 by a finer technology, the capacity of the ferroelectric capacitor C and the memory capacitors C1 and C2 can be increased.

Note that the solid-state imaging device of the present embodiment may include the antiferroelectric capacitor C′ or the paraelectric capacitor C″ instead of the ferroelectric capacitor C, and may include the memory capacitors C1′ and C2′ or the memory capacitors C1″ and C2″ instead of the memory capacitors C1 and C2.

### Sixth Embodiment

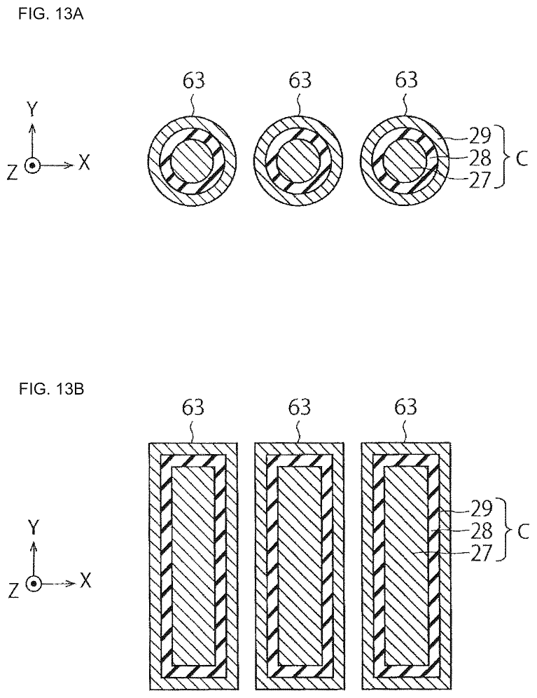

FIG. 13 is a transverse cross-sectional view illustrating two examples of the structure of the solid-state imaging device of the sixth embodiment.

A of FIG. 13 illustrates a first example of an XY cross section (cross section) of the ferroelectric capacitor C illustrated in FIG. 4. In A of FIG. 13, each contact hole 63 has a circular XY cross section, and thus has a columnar shape extending in the Z direction.

B of FIG. 13 illustrates a second example of the XY cross section (cross section) of the ferroelectric capacitor C illustrated in FIG. 4. In B of FIG. 13, each contact hole 63 has a linear XY cross section extending in the Y direction, and thus has a planar shape extending in the Y direction and the Z direction.

As described above, the ferroelectric capacitor C of the present embodiment may have any shape. For example, the XY cross section of each contact hole 63 may be an elliptical shape or a quadrangular shape instead of a circular shape, or may be a curved shape instead of a linear shape. Note that the structure of the present embodiment is also applicable to the antiferroelectric capacitor C′ and the paraelectric capacitor C″.

### Seventh Embodiment

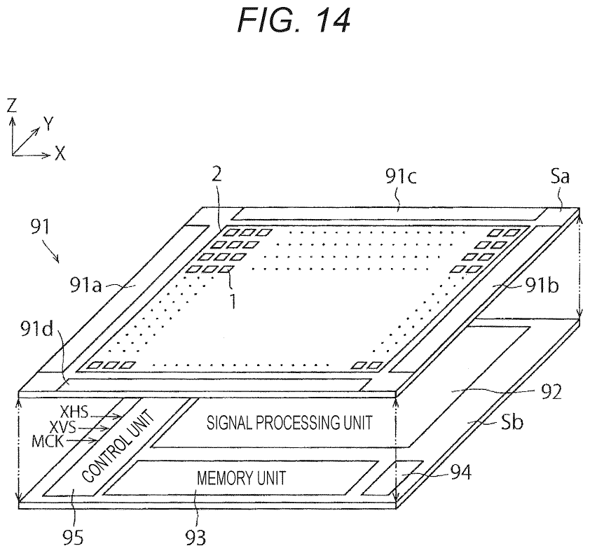

FIG. 14 is a perspective view illustrating a structure of a solid-state imaging device of a seventh embodiment.

The solid-state imaging device of the present embodiment has a two-layer structure including the upper layer Sa and the lower layer Sb. The upper layer Sa includes the pixel array region 2 including the plurality of pixels 1 and a plurality of connecting portions 91. These connecting portions 91 include a pad portion 91a, a pad portion 91b, a via portion 91c, and a via portion 91d. The lower layer Sb includes a signal processing unit 92, a memory unit 93, a data processing unit 94, and a control unit 95. The configuration of the solid-state imaging device illustrated in FIG. 1 can be realized by, for example, the structure illustrated in FIG. 14.

The pad portion 91a, the pad portion 91b, the via portion 91c, and the via portion 91d are arranged around the pixel array region 2. The pad portions 91a and 91b are provided to electrically connect the solid-state imaging device of the present embodiment to another device. The via portions 91c and 91d are provided to electrically connect the upper layer Sa of the present embodiment to the lower layer Sb.

The signal processing unit 92 performs various processes on the signal from the pixel array region 2. The memory unit 93 stores the image data processed by the signal processing unit 92. The data processing unit 94 performs various processes on the image data stored in the memory unit 93, and outputs the processed image data to another device. The control unit 95 controls various operations of the solid-state imaging device of the present embodiment, and functions as, for example, the control circuit 3 illustrated in FIG. 1.

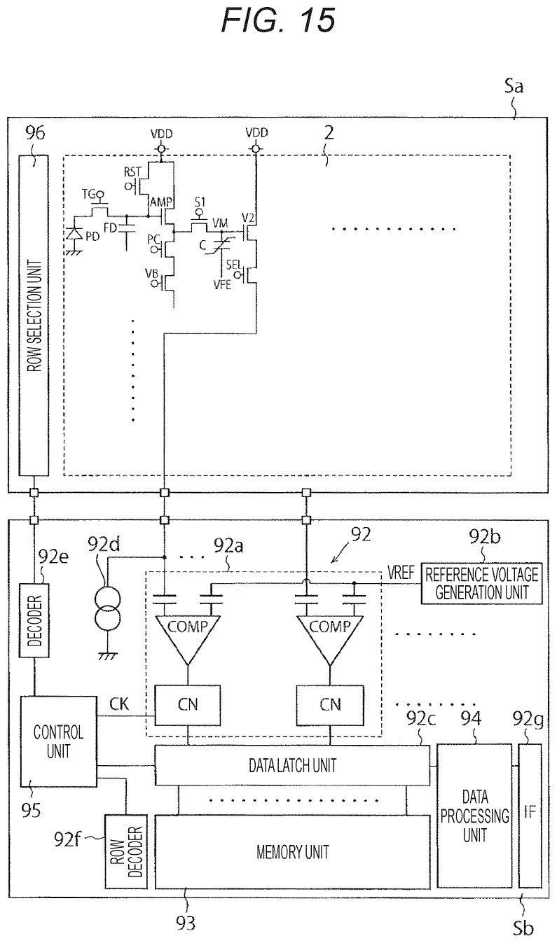

FIG. 15 is a block diagram illustrating a configuration of a solid-state imaging device of a seventh embodiment.

FIG. 15 illustrates the pixel array region 2 and the row selection unit 96 in the upper layer Sa, and the signal processing unit 92, the memory unit 93, the data processing unit 94, and the control unit 95 in the lower layer Sb. The pixel 1 in the pixel array region 2 in FIG. 15 has the configuration illustrated in FIG. 2. Furthermore, the signal processing unit 92 includes an analog to digital (A/D) converter 92a, a reference voltage generation unit 92b, a data latch unit 92c, a current source 92d, a decoder 92e, a row decoder 92f, and an interface (I/F) unit 92g.

The A/D converter 92a includes two comparators CMP and two counters CN, and converts a signal from the pixel array region 2 from an analog signal to a digital signal. The reference voltage generation unit 92b generates a reference signal VREF for the A/D converter 92a. The data latch unit 92c latches the digital signal from the A/D converter 92a. The current source 92d supplies a constant current to the A/D converter 92a. Under the control of the control unit 95, the decoder 92e and the row decoder 92f specify a row address and provide an address signal for specifying a selected row to the row selection unit 96. The I/F unit 92g functions as an interface for outputting processed image data to another device.

Note that the configuration of the solid-state imaging device illustrated in FIG. 1 may be implemented by the structure illustrated in FIG. 14 or may be implemented by another structure.

### Eighth to Eleventh Embodiments

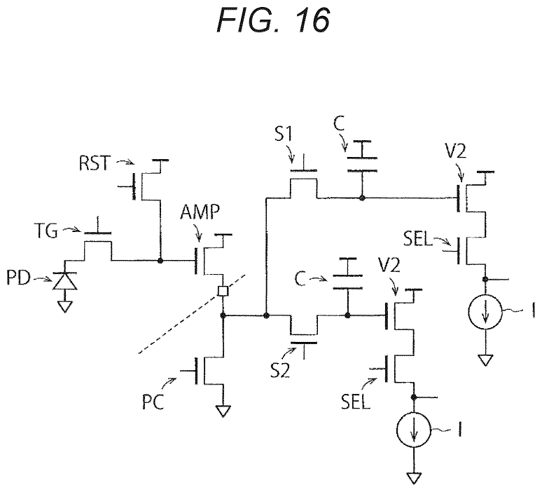

The circuit configuration illustrated in FIG. 2 may be replaced with the circuit configurations illustrated in FIGS. 16 to 19. Hereinafter, the circuit configuration illustrated in FIGS. 16 to 19 will be described.

FIG. 16 is a circuit diagram showing a configuration of a solid-state imaging device of an eighth embodiment.

The pixel 1 illustrated in FIG. 16 includes a switch transistor S2, a ferroelectric capacitor C provided at a post stage of the switch transistor S2, a post-amplifying transistor V2, and a selection transistor SEL, in addition to the components illustrated in FIG. 2. In FIG. 16, the configurations of the switch transistor S2, the ferroelectric capacitor C provided at the post stage of the switch transistor S2, the post-amplifying transistor V2, and the selection transistor SEL are the same as the configurations of the switch transistor S1, the ferroelectric capacitor C provided at the post stage of the switch transistor S1, the post-amplifying transistor V2, and the selection transistor SEL, respectively. The pixel 1 illustrated in FIG. 16 further includes two current sources I provided at the post stage of the switch transistors S1 and S2.

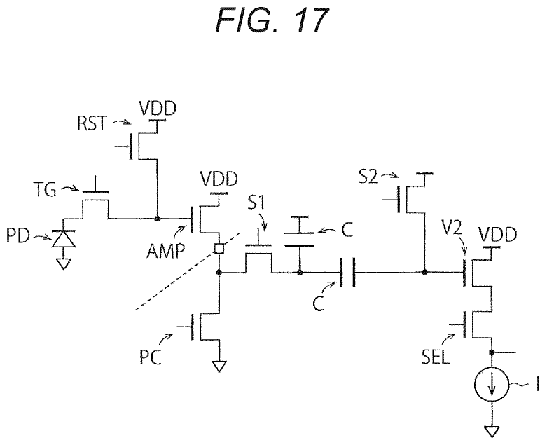

FIG. 17 is a circuit diagram illustrating a configuration of a solid-state imaging device of a ninth embodiment.

The pixel 1 illustrated in FIG. 17 includes, in addition to the components illustrated in FIG. 2, the ferroelectric capacitor C provided between the switch transistor S1 and the post-amplifying transistor V2, and the switch transistor S2 electrically connected to the ferroelectric capacitor C and the post-amplifying transistor V2. The pixel 1 illustrated in FIG. 17 further includes a current source I provided at a post stage of the selection transistor SEL.

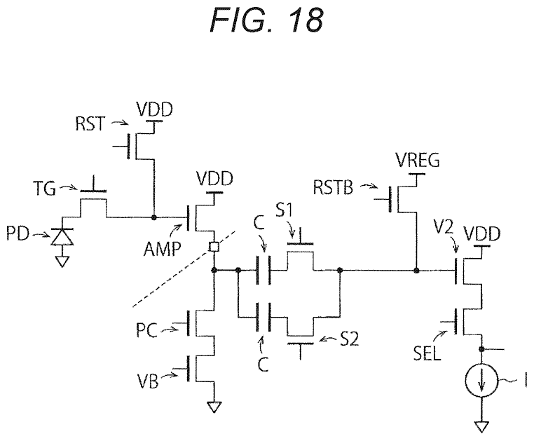

FIG. 18 is a circuit diagram illustrating a configuration of a solid-state imaging device of a tenth embodiment.

The pixel 1 illustrated in FIG. 18 includes, in addition to the components illustrated in FIG. 2, the switch transistor S2 connected in parallel with the switch transistor S1, and a transistor RSTB electrically connected to the switch transistors S1 and S2 and the post-amplifying transistor V2. The pixel 1 illustrated in FIG. 18 further includes the current source I provided at the post stage of the selection transistor SEL.

The pixel 1 illustrated in FIG. 18 further includes two ferroelectric capacitors C. However, one of these ferroelectric capacitors C is disposed between the amplifying transistor AMP and the switch transistor S1, and the other of these ferroelectric capacitors C is disposed between the amplifying transistor AMP and the switch transistor S2. One electrode of the ferroelectric capacitors C is electrically connected to the source or the drain of the amplifying transistor AMP.

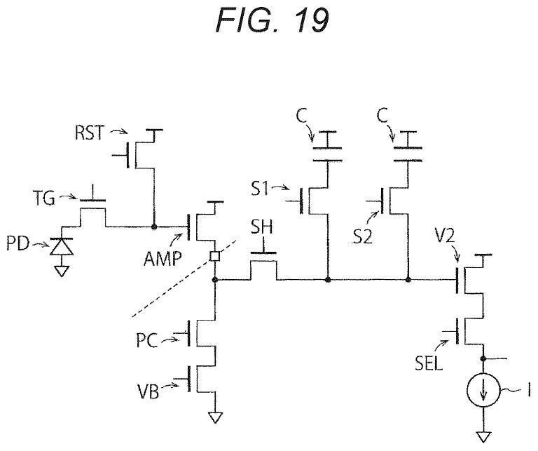

FIG. 19 is a circuit diagram illustrating a configuration of a solid-state imaging device of an eleventh embodiment.

The pixel 1 shown in FIG. 19 includes the switch transistor S2, the ferroelectric capacitor C provided at a post stage of the switch transistor S2, and a switch transistor SH, in addition to the components shown in FIG. 2.

The switch transistor SH is provided between the amplifying transistor AMP and the post-amplifying transistor V2. The switch transistor S1 is electrically connected to the switch transistor SH and the post-amplifying transistor V2, and the switch transistor S2 is also electrically connected to the switch transistor SH and the post-amplifying transistor V2. The ferroelectric capacitor C at the post stage of the switch transistor S1 is electrically connectable to the amplifying transistor AMP via the switch transistors SH and S1. Similarly, the ferroelectric capacitor C at the post stage of the switch transistor S2 is electrically connectable to the amplifying transistor AMP via the switch transistors SH and S2.

Note that the configurations of the eighth to eleventh embodiments can be applied not only to the ferroelectric capacitor C but also to the antiferroelectric capacitor C′ and the paraelectric capacitor C″.

### Application Example

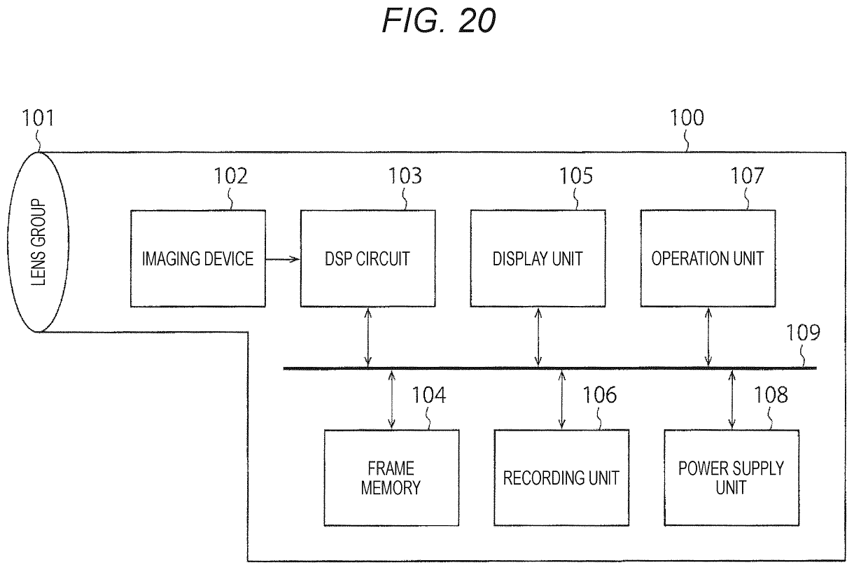

FIG. 20 is a block diagram illustrating a configuration example of an electronic device. The electric device illustrated in FIG. 20 is a camera 100.

The camera 100 includes an optical unit 101 including a lens group and the like, an imaging device 102 that is the solid-state imaging device of any of the first to eleventh embodiments, a digital signal processor (DSP) circuit 103 that is a camera signal processing circuit, a frame memory 104, a display unit 105, a recording unit 106, an operation unit 107, and a power supply unit 108. Furthermore, the DSP circuit 103, the frame memory 104, the display unit 105, the recording unit 106, the operation unit 107, and the power supply unit 108 are connected to each other via a bus line 109.

The optical unit 101 captures incident light (image light) from a subject and forms an image on an imaging surface of the imaging device 102. The imaging device 102 converts an amount of incident light formed into an image on the imaging surface by the optical unit 101 into an electric signal on a pixel-by-pixel basis and outputs the electric signal as a pixel signal.

The DSP circuit 103 performs signal processing on the pixel signal output from the imaging device 102. The frame memory 104 is a memory for storing one screen of a moving image or a still image captured by the imaging device 102.

The display unit 105 includes, for example, a panel type display device such as a liquid crystal panel or an organic EL panel, and displays a moving image or a still image captured by the imaging device 102. The recording unit 106 records a moving image or a still image captured by the imaging device 102 on a recording medium such as a hard disk or a semiconductor memory.

The operation unit 107 issues operation commands for various functions of the camera 100 in response to an operation performed by a user. The power supply unit 108 appropriately supplies various power supplies, which are operation power supplies for the DSP circuit 103, the frame memory 104, the display unit 105, the recording unit 106, and the operation unit 107, to these power supply targets.

It can be expected to acquire a satisfactory image by using the solid-state imaging device of any of the first to eleventh embodiments as the imaging device 102.

The solid-state imaging device can be applied to various other products. For example, the solid-state imaging device may be mounted on any type of moving bodies such as vehicles, electric vehicles, hybrid electric vehicles, motorcycles, bicycles, personal mobility, airplanes, drones, ships, and robots.

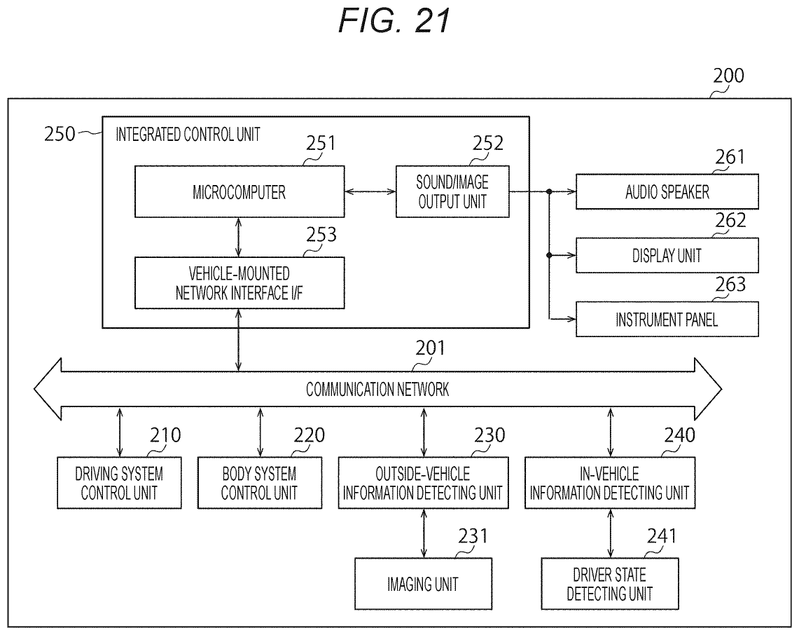

FIG. 21 is a block diagram illustrating a configuration example of a moving body control system. The moving body control system illustrated in FIG. 21 is a vehicle control system 200.

The vehicle control system 200 includes a plurality of electronic control units connected to each other via a communication network 201. In the example illustrated in FIG. 21, the vehicle control system 200 includes a driving system control unit 210, a body system control unit 220, an outside-vehicle information detecting unit 230, an in-vehicle information detecting unit 240, and an integrated control unit 250. Moreover, FIG. 21 illustrates a microcomputer 251, a sound/image output unit 252, and a vehicle-mounted network interface (I/F) 253 as components of the integrated control unit 250.

The driving system control unit 210 controls the operation of devices related to a driving system of a vehicle in accordance with various types of programs. For example, the driving system control unit 210 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 220 controls the operation of various types of devices provided to a vehicle body in accordance with various types of programs. For example, the body system control unit 220 functions as a control device for a smart key system, a keyless entry system, a power window device, or various types of lamps (for example, a head lamp, a backup lamp, a brake lamp, a turn signal, a fog lamp, or the like). In this case, radio waves transmitted from a mobile device as an alternative to a key or signals of various types of switches can be input to the body system control unit 220. The body system control unit 220 receives inputs of such radio waves or signals, and controls a door lock device, the power window device, the lamps, or the like of the vehicle.

The outside-vehicle information detecting unit 230 detects information on the outside of the vehicle including the vehicle control system 200. The outside-vehicle information detecting unit 230 is connected with, for example, an imaging unit 231. The outside-vehicle information detecting unit 230 makes the imaging unit 231 capture an image of the outside of the vehicle, and receives the captured image from the imaging unit 231. On the basis of the received image, the outside-vehicle information detecting unit 230 may perform processing of detecting an object such as a human, an automobile, an obstacle, a sign, a character on a road surface, or the like, or processing of detecting a distance thereto.

The imaging unit 231 is an optical sensor that receives light and that outputs an electric signal corresponding to the amount of received light. The imaging unit 231 can output the electric signal as an image, or can output the electric signal as information on a measured distance. The light received by the imaging unit 231 may be visible light, or may be invisible light such as infrared light. The imaging unit 231 includes the solid-state imaging device of any of the first to eleventh embodiments.

The in-vehicle information detecting unit 240 detects information on the inside of the vehicle equipped with the vehicle control system 200. The in-vehicle information detecting unit 240 is, for example, connected with a driver state detecting unit 241 that detects a state of a driver. For example, the driver state detecting unit 241 includes a camera that captures an image of the driver, and on the basis of detection information input from the driver state detecting unit 241, the in-vehicle information detecting unit 240 may calculate a degree of fatigue of the driver or a degree of concentration of the driver, or may determine whether or not the driver is dozing off. The camera may include the solid-state imaging device of any of the first to eleventh embodiments, and may be, for example, the camera 100 illustrated in FIG. 20.

The microcomputer 251 can calculate a control target value for the driving force generating device, the steering mechanism, or the braking device on the basis of the information on the inside or outside of the vehicle obtained by the outside-vehicle information detecting unit 230 or the in-vehicle information detecting unit 240, and output a control command to the driving system control unit 210. For example, the microcomputer 251 can perform cooperative control intended to implement functions of an advanced driver assistance system (ADAS), the functions including collision avoidance or shock mitigation for the vehicle, following traveling based on a following distance, vehicle speed maintaining traveling, a warning of collision of the vehicle, a warning of deviation of the vehicle from a lane, and the like.

Furthermore, the microcomputer 251 can perform cooperative control intended for automated driving, which makes the vehicle travel autonomously without depending on the operation of the driver, or the like, by controlling the driving force generating device, the steering mechanism, the braking device, or the like on the basis of the information around the vehicle obtained by the outside-vehicle information detecting unit 230 or the in-vehicle information detecting unit 240.

Furthermore, the microcomputer 251 can output a control command to the body system control unit 220 on the basis of the information on the outside of the vehicle obtained by the outside-vehicle information detecting unit 230. For example, the microcomputer 251 can perform cooperative control for the purpose of preventing glare, such as switching from a high beam to a low beam, by controlling the headlamp according to the position of a preceding vehicle or an oncoming vehicle detected by the outside-vehicle information detecting unit 230.

The sound/image output unit 252 transmits an output signal of at least one of a sound or an image to an output device that can visually or auditorily provide information to an occupant of the vehicle or the outside of the vehicle. In the example of FIG. 21, an audio speaker 261, a display unit 262, and an instrument panel 263 are illustrated as such an output device. The display unit 262 may, for example, include an on-board display or a head-up display.

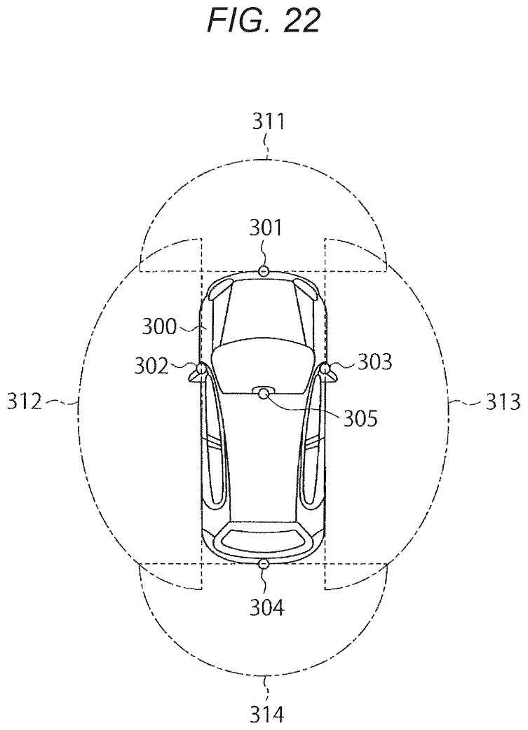

FIG. 22 is a plan view illustrating a specific example of a setting position of the imaging unit 231 in FIG. 21.

A vehicle 300 illustrated in FIG. 22 includes imaging units 301, 302, 303, 304, and 305 as the imaging unit 231. The imaging units 301, 302, 303, 304, and 305 are, for example, provided at positions on a front nose, side mirrors, a rear bumper, and a back door of the vehicle 300, and on an upper portion of a windshield in the interior of the vehicle.

The imaging unit 301 provided on the front nose mainly acquires an image of the front of the vehicle 300. The imaging unit 302 provided on the left side mirror and the imaging unit 303 provided on the right side mirror mainly acquire images of the sides of the vehicle 300. The imaging unit 304 provided to the rear bumper or the back door mainly acquires an image of the rear of the vehicle 300. The imaging unit 305 provided to the upper portion of the windshield in the interior of the vehicle mainly acquires an image of the front of the vehicle 300. The imaging unit 305 is used to detect, for example, a preceding vehicle, a pedestrian, an obstacle, a traffic light, a traffic sign, a lane, and the like.

FIG. 22 illustrates an example of imaging ranges of the imaging units 301, 302, 303, and 304 (hereinafter referred to as “imaging units 301 to 304”). An imaging range 311 represents the imaging range of the imaging unit 301 provided to the front nose. An imaging range 312 represents the imaging range of the imaging unit 302 provided to the left side mirror. An imaging range 313 represents the imaging range of the imaging unit 303 provided to the right side mirror. An imaging range 314 represents the imaging range of the imaging unit 304 provided to the rear bumper or the back door. For example, an overhead view of the vehicle 300 as viewed from above is obtained by superimposing image data captured by the imaging units 301 to 304. Hereinafter, the imaging ranges 311, 312, 313, and 314 are referred to as the “imaging ranges 311 to 314”.

At least one of the imaging units 301 to 304 may have a function of acquiring distance information. For example, at least one of the imaging units 301 to 304 may be a stereo camera including a plurality of imaging devices or an imaging device including pixels for phase difference detection.

For example, the microcomputer 251 (FIG. 21) calculates a distance to each three-dimensional object within the imaging ranges 311 to 314 and a temporal change in the distance (relative speed with respect to the vehicle 300) on the basis of the distance information obtained from the imaging units 301 to 304. On the basis of the calculation results, the microcomputer 251 can extract, as a preceding vehicle, a nearest three-dimensional object that is present on a traveling path of the vehicle 300 and travels in substantially the same direction as the vehicle 300 at a predetermined speed (for example, equal to or more than 0 km/h). Moreover, the microcomputer 251 can set a following distance to be maintained in front of a preceding vehicle in advance, and perform automatic brake control (including following stop control), automatic acceleration control (including following start control), or the like. According to this example, the cooperative control intended for automated driving that makes the vehicle travel autonomously and the like can be performed without depending on the operation of the driver.

For example, the microcomputer 251 can classify three-dimensional object data related to three-dimensional objects into a two-wheeled vehicle, a standard-sized vehicle, a large-sized vehicle, a pedestrian, a utility pole, and other three-dimensional objects on the basis of the distance information obtained from the imaging units 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating a risk of collision with each obstacle, and in a situation in which the collision risk is equal to or higher than a set value and there is thus a possibility of collision, the microcomputer 251 outputs a warning to the driver via the audio speaker 261 or the display unit 262, and performs forced deceleration or avoidance steering via the driving system control unit 210 to assist in driving to avoid collision.

At least one of the imaging units 301 to 304 may be an infrared camera that detects infrared light. The microcomputer 251 can, for example, recognize a pedestrian by determining whether or not there is a pedestrian in images captured by the imaging units 301 to 304. Such recognition of a pedestrian is, for example, performed by a procedure of extracting characteristic points in the images captured by the imaging units 301 to 304 as infrared cameras and a procedure of determining whether or not an object is a pedestrian by performing pattern matching processing on a series of characteristic points representing the contour of the object. In a case where the microcomputer 251 determines that there is a pedestrian in the captured images captured by the imaging units 301 to 304 and recognizes the pedestrian, the sound/image output unit 252 controls the display unit 262 so that a square contour line for emphasis is displayed in a superimposed manner on the recognized pedestrian. Furthermore, the sound/image output unit 252 may also control the display unit 262 so that an icon or the like representing the pedestrian is displayed at a desired position.

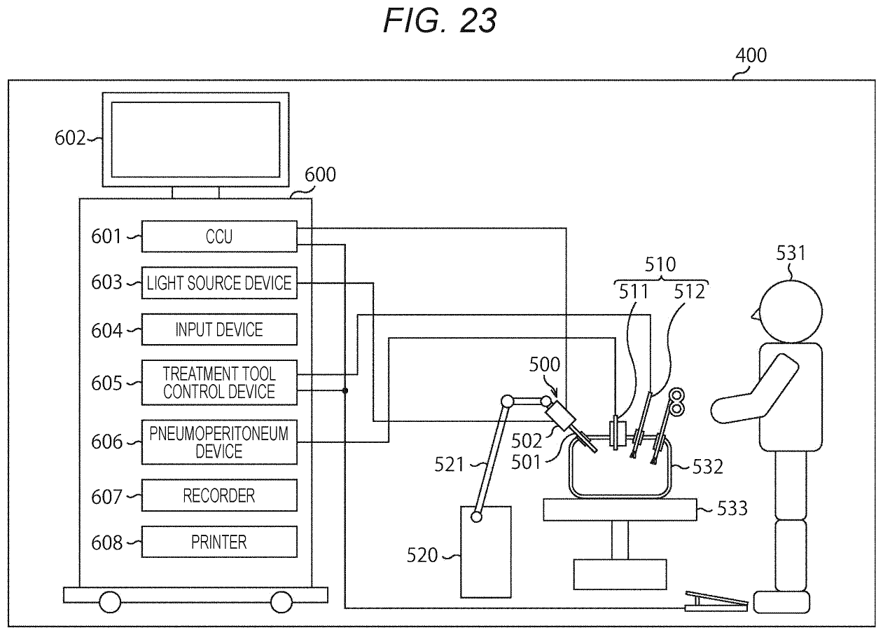

FIG. 23 is a diagram illustrating an example of a schematic configuration of an endoscopic surgery system to which the technology according to the present disclosure (the present technology) can be applied.

In FIG. 23, a state is illustrated in which a surgeon (medical doctor) 531 is using an endoscopic surgery system 400 to perform surgery for a patient 532 on a patient bed 533. As illustrated, the endoscopic surgery system 400 includes an endoscope 500, other surgical tools 510 such as a pneumoperitoneum tube 511 and an energy treatment tool 512, a supporting arm device 520 for supporting the endoscope 500, and a cart 600 on which various devices for endoscopic surgery are mounted.

The endoscope 500 includes a lens barrel 501 having a region of a predetermined length from a distal end thereof to be inserted into a body cavity of the patient 532, and a camera head 502 connected to a proximal end of the lens barrel 501. Although the illustrated example illustrates the endoscope 500 configured as a so-called rigid endoscope having a rigid lens barrel 501, the endoscope 500 may be a so-called flexible endoscope having a flexible lens barrel.

An opening in which an objective lens is fitted is provided at the distal end of the lens barrel 501. A light source device 603 is connected to the endoscope 500, and light generated by the light source device 603 is guided to the distal end of the lens barrel by a light guide extending in the lens barrel 501 and is emitted to an observation target in the body cavity of the patient 532 through the objective lens. Note that the endoscope 500 may be a forward-viewing endoscope, an oblique-viewing endoscope, or a side-viewing endoscope.

An optical system and an imaging element are provided in the camera head 502, and light reflected by the observation target (observation light) is collected on the imaging element by the optical system. The imaging element photoelectrically converts the observation light and generates an electric signal corresponding to the observation light, that is, an image signal corresponding to an observation image. The image signal is transmitted to a camera control unit (CCU) 601 as RAW data.

The CCU 601 includes a central processing unit (CPU), a graphics processing unit (GPU), and the like, and integrally controls the operations of the endoscope 500 and a display device 602. Moreover, the CCU 601 receives the image signal from the camera head 502 and applies, on the image signal, various types of image processing, for example, development processing (demosaicing processing) or the like for displaying an image based on the image signal.

The display device 602 displays the image based on the image signal which has been subjected to the image processing by the CCU 601 under the control of the CCU 601.

The light source device 603 includes, for example, a light source such as a light emitting diode (LED), and supplies irradiation light for imaging a surgical site or the like to the endoscope 500.

An input device 604 is an input interface for the endoscopic surgery system 11000. A user may input various types of information and instructions to the endoscopic surgery system 400 via the input device 604. For example, the user inputs an instruction and the like to change an imaging condition (type of irradiation light, magnification, focal length and the like) by the endoscope 500.

A treatment tool control device 605 controls driving of the energy treatment tool 512 for tissue cauterization, incision, blood vessel sealing, and the like. A pneumoperitoneum device 606 sends gas into the body cavity of the patient 532 via the pneumoperitoneum tube 511 in order to inflate the body cavity for a purpose of securing a field of view by the endoscope 500 and securing work space for the surgeon. A recorder 607 is a device that can record various types of information regarding surgery. A printer 608 is a device that can print various types of information regarding surgery in various formats such as a text, an image, or a graph.

Note that, the light source device 603 which supplies the irradiation light for imaging the surgical site to the endoscope 500 may include, for example, an LED, a laser light source, or a white light source obtained by combining these. In a case where the white light source includes a combination of RGB laser light sources, because an output intensity and an output timing of each color (each wavelength) can be controlled with high accuracy, the light source device 603 can adjust white balance of a captured image. Furthermore, in this case, by irradiating the observation target with the laser light from each of the R, G, and B laser light sources in time division and controlling driving of the imaging element of the camera head 502 in synchronism with the irradiation timing, images corresponding to R, G, and B can be captured in time division. According to this method, a color image can be obtained even if color filters are not provided for the imaging element.

Furthermore, the driving of the light source device 603 may be controlled such that the intensity of light to be output is changed every predetermined time. The driving of the imaging element of the camera head 502 is controlled in synchronization with a timing of changing the light intensity to obtain the images in time division, and the obtained images are synthesized to enable generation of an image with a high dynamic range that does not have so-called black defect and halation.

Furthermore, the light source device 603 may be able to supply light in a predetermined wavelength band adapted to special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source device 603 can be configured to supply narrow band light and/or excitation light adapted to such special light observation.

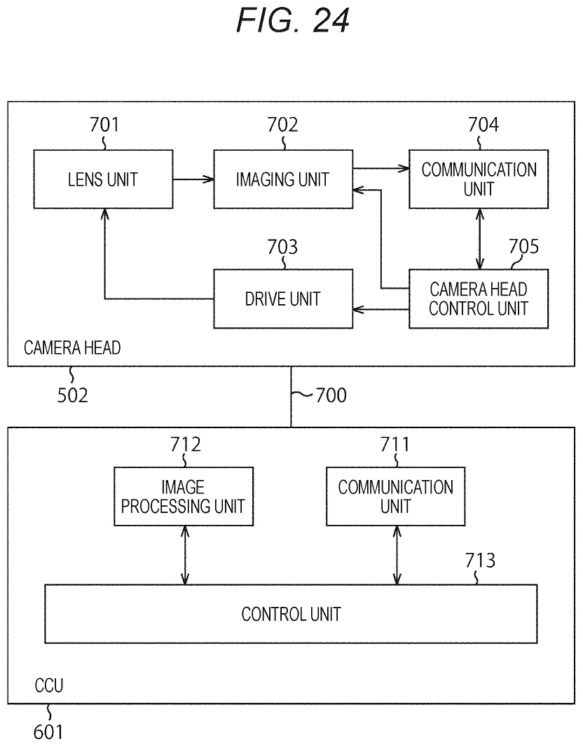

FIG. 24 is a block diagram illustrating an example of functional configurations of the camera head 502 and the CCU 601 illustrated in FIG. 23.

The camera head 502 includes a lens unit 701, an imaging unit 702, a drive unit 703, a communication unit 704, and a camera head control unit 705. The CCU 601 includes a communication unit 711, an image processing unit 712, and a control unit 713. The camera head 502 and the CCU 601 are connected to each other communicably by a transmission cable 700.

The lens unit 701 is an optical system provided at a connecting portion with the lens barrel 501. The observation light captured from the distal end of the lens barrel 501 is guided to the camera head 502 and enters the lens unit 701. The lens unit 701 is configured by combining a plurality of lenses including a zoom lens and a focus lens.

The imaging unit 702 includes an imaging element. The number of imaging elements included in the imaging unit 702 may be one (so-called single plate type) or two or more (so-called multiple plate type). In a case where the imaging unit 702 is configured as the multiple plate type, for example, image signals corresponding to R, G, and B may be generated by the respective imaging elements, and a color image may be obtained by combining the generated image signals. Alternatively, the imaging unit 702 may include a pair of imaging elements for obtaining right-eye and left-eye image signals corresponding to three-dimensional (3D) display. By performing the 3D display, the surgeon 531 can grasp a depth of a living body tissue in a surgical site more accurately. Note that, in a case where the imaging unit 702 is configured as the multiple plate type, a plurality of systems of lens units 701 may be provided so as to correspond to the respective imaging elements. The imaging unit 702 is, for example, the solid-state imaging device of any of the first to eleventh embodiments.

Furthermore, the imaging unit 702 is not necessarily provided in the camera head 502. For example, the imaging unit 702 may be provided inside the lens barrel 501 immediately behind the objective lens.

The drive unit 703 includes an actuator and moves the zoom lens and the focusing lens of the lens unit 701 by a predetermined distance along an optical axis under the control of the camera head control unit 705. With this arrangement, the magnification and focal point of the image captured by the imaging unit 702 may be appropriately adjusted.

The communication unit 704 includes a communication device for transmitting and receiving various types of information to and from the CCU 601. The communication unit 704 transmits the image signal obtained from the imaging unit 702 as RAW data to the CCU 601 via the transmission cable 700.

Furthermore, the communication unit 704 receives a control signal for controlling driving of the camera head 502 from the CCU 601 and supplies the control signal to the camera head control unit 705. The control signal includes information relating to image pickup conditions such as, for example, information that a frame rate of a picked up image is designated, information that an exposure value upon image picking up is designated and/or information that a magnification and a focal point of a picked up image are designated.

Note that the imaging conditions such as the frame rate, exposure value, magnification, and focus described above may be appropriately specified by the user, or may be automatically set by the control unit 713 of the CCU 601 on the basis of the acquired image signal. In the latter case, the endoscope 500 is equipped with a so-called auto exposure (AE) function, an auto focus (AF) function, and an auto white balance (AWB) function.

The camera head control unit 705 controls the driving of the camera head 502 on the basis of the control signal from the CCU 601 received via the communication unit 704.

The communication unit 711 includes a communication device for transmitting and receiving various types of information to and from the camera head 502. The communication unit 711 receives the image signal transmitted from the camera head 502 via the transmission cable 700.

Furthermore, the communication unit 711 transmits the control signal for controlling the driving of the camera head 502 to the camera head 502. The image signal and the control signal can be transmitted by electrical communication, optical communication or the like.

The image processing unit 712 performs various types of image processing on the image signal which is the RAW data transmitted from the camera head 502.

The control unit 713 performs various types of control regarding imaging of the surgical site and the like by the endoscope 500 and display of the captured image obtained by the imaging of the surgical site and the like. For example, the control unit 713 generates the control signal for controlling the driving of the camera head 502.

Furthermore, the control unit 713 allows the display device 602 to display the captured image including the surgical site and the like on the basis of the image signal subjected to the image processing by the image processing unit 712. At this time, the control unit 713 may recognize various objects in the captured image using various image recognition technologies. For example, the control unit 713 may detect edge shapes, colors, and the like of the objects included in the captured image, to recognize the surgical tool such as forceps, a specific living body site, bleeding, mist when the energy treatment tool 512 is used, and the like. At the time of causing the display device 602 to display the captured image, the control unit 713 may superimpose various types of surgery assistance information on the image of the surgical site using the recognition result. The surgery assistance information is displayed to be superimposed and presented to the surgeon 531, which can reduce the burden on the surgeon 531 and enable the surgeon 531 to reliably proceed with surgery.

The transmission cable 700 connecting the camera head 502 and the CCU 601 is an electric signal cable compatible with communication of electric signals, an optical fiber compatible with optical communication, or a composite cable thereof.

Here, in the illustrated example, the communication is performed wired using the transmission cable 700, but the communication between the camera head 502 and the CCU 601 may be performed wirelessly.

Although the embodiments of the present disclosure have been described above, these embodiments may be implemented with various modifications within a scope not departing from the gist of the present disclosure. For example, two or more embodiments may be implemented in combination.

Note that the present disclosure can also have the following configurations.

(1)

A solid-state imaging device including:
a first substrate;
a photoelectric conversion unit provided in the first substrate;
a floating diffusion unit provided in the first substrate;
a pixel transistor electrically connected to the floating diffusion unit; and
a capacitor including a first electrode electrically connected or connectable to the pixel transistor, a second electrode different from the first electrode, and a first ferroelectric film or a first antiferroelectric film provided between the first electrode and the second electrode.
   (2)

The solid-state imaging device according to (1), in which the pixel transistor is an amplifying transistor having a gate electrically connected to the floating diffusion unit and a source or a drain electrically connected to or connectable to the first electrode.

(3)

The solid-state imaging device according to (1), in which the first electrode is electrically connectable to the pixel transistor via a switch transistor.

(4)

The solid-state imaging device according to (1), in which the first ferroelectric film or the first antiferroelectric film contains hafnium (Hf), zirconium (Zr), niobium (Nb), scandium (Sc), yttrium (Y), lanthanum (La), germanium (Ge), or silicon (Si).

(5)

The solid-state imaging device according to (1),
in which the capacitor is provided on a first surface side of the first substrate, and
the solid-state imaging device further includes a lens provided on a second surface side of the first substrate.
   (6)

The solid-state imaging device according to (1), further including a second substrate bonded to the first substrate,
in which the pixel transistor and the capacitor are provided between the first substrate and the second substrate.
   (7)

The solid-state imaging device according to (6),
in which the pixel transistor is provided in a first insulating film provided on the first substrate, and
the capacitor is provided in a second insulating film provided on the second substrate and located between the second substrate and the first insulating film.
   (8)

The solid-state imaging device according to (6), further including a third substrate provided between the first substrate and the second substrate,
in which the capacitor is provided between the second substrate and the third substrate.
   (9)

The solid-state imaging device according to (1), in which a capacity of the capacitor is controlled to be set to only one of a plurality of types of values.

(10)

The solid-state imaging device according to (1), further including a memory including a third electrode and a fourth electrode different from the third electrode,
in which the memory
includes a second ferroelectric film between the third electrode and the fourth electrode in a case where the capacitor includes the first ferroelectric film, and
includes a second antiferroelectric film between the third electrode and the fourth electrode in a case where the capacitor includes the first antiferroelectric film.
   (11)

The solid-state imaging device according to (10),
in which the third electrode is formed of the same material as the first electrode,
the fourth electrode is formed of the same material as the second electrode, and
the second ferroelectric film or the second antiferroelectric film is formed of the same material as the first ferroelectric film or the first antiferroelectric film.
   (12)

A solid-state imaging device including:
a first substrate;
a photoelectric conversion unit provided in the first substrate;
a floating diffusion unit provided in the first substrate;
a capacitor including a first electrode provided on a first surface side or a second surface side of the first substrate, a second electrode different from the first electrode, and a first ferroelectric film, a first antiferroelectric film, or a first paraelectric film provided between the first electrode and the second electrode; and
a memory including a third electrode and a fourth electrode different from the third electrode,
in which the memory
includes a second ferroelectric film between the third electrode and the fourth electrode in a case where the capacitor includes the first ferroelectric film,
includes a second antiferroelectric film between the third electrode and the fourth electrode in a case where the capacitor includes the first antiferroelectric film, and
includes a second paraelectric film between the third electrode and the fourth electrode in a case where the capacitor includes the first paraelectric film.
   (13)

The solid-state imaging device according to (12),
in which the third electrode is formed of the same material as the first electrode,
the fourth electrode is formed of the same material as the second electrode, and
the second ferroelectric film, the second antiferroelectric film, or the second paraelectric film is formed of the same material as the first ferroelectric film, the first antiferroelectric film, or the second paraelectric film.
   (14)

The solid-state imaging device according to (12), in which the first and second ferroelectric films, the first and second antiferroelectric films, or the first and second paraelectric films contain hafnium (Hf), zirconium (Zr), niobium (Nb), scandium (Sc), yttrium (Y), lanthanum (La), germanium (Ge), or silicon (Si).

(15)

The solid-state imaging device according to (12),
in which the capacitor and the memory are provided on the first surface side of the first substrate, and
the solid-state imaging device further includes a lens provided on the second surface side of the first substrate.
   (16)

The solid-state imaging device according to (12), further including a pixel transistor electrically connected to the floating diffusion unit,
in which the first electrode is electrically connected or connectable to the pixel transistor.
   (17)

The solid-state imaging device according to (16), further including a second substrate bonded to the first substrate,
in which the pixel transistor, the capacitor, and the memory are provided between the first substrate and the second substrate.
   (18)

The solid-state imaging device according to (17),
in which the pixel transistor is provided in a first insulating film provided on the first substrate, and
the capacitor and the memory are provided in a second insulating film provided on the second substrate and located between the second substrate and the first insulating film.
   (19)

The solid-state imaging device according to (17), further including a third substrate provided between the first substrate and the second substrate,
in which the capacitor and the memory are provided between the second substrate and the third substrate.
   (20)

The solid-state imaging device according to (12), in which the capacitor and the memory have portions provided in the same transverse plane.

### REFERENCE SIGNS LIST

1 Pixel
2 Pixel array region
3 Control circuit
4 Vertical drive circuit
5 Column signal processing circuit
6 Horizontal drive circuit
7 Output circuit
8 Vertical signal line
9 Horizontal signal line
11 Substrate
11a Well region
11b Diffusion region
11c Diffusion region
11d Diffusion region
11e Diffusion region
11f Diffusion region
12 Element isolation insulating film
13 Gate insulating film
14 Gate electrode
15 Sidewall insulating film
16 Interlayer insulating film
21 Contact plug
22 Wiring
22′ Wiring
22″ Wiring
23 Contact hole
24 Wiring
25 Wiring
26 Wiring
27 Electrode
28 Ferroelectric film
29 Electrode
31 Via plug
32 Wiring
32′ Wiring
32″ Wiring
33 Via plug
34 Wiring
34″ Wiring
41 On-chip filter
42 On-chip lens
51 Substrate
52 Gate insulating film
53 Gate electrode
54 Sidewall insulating film
55 Interlayer insulating film
61 Contact plug
61′ Contact plug
62 Wiring
62′ Wiring
63 Contact hole
63′ Contact hole
64 Wiring
64′ Wiring
65 Wiring
65′ Wiring
65″ Wiring
66 Wiring
67 Wiring
68 Wiring
71 Circuit region
72 Sample hold region
73 Memory region
81 Ferroelectric film
82 Paraelectric film
91 Connecting portion
91a Pad portion
91b Pad portion
91c Via portion
91d Via portion
92 Signal processing unit
92a A/D converter
92b Reference voltage generation unit
92c Data latch unit
92d Current source
92e Decoder
92f Row decoder
92g I/F unit
93 Memory unit
94 Data processing unit
95 Control unit
96 Row selection unit

1. A solid-state imaging device comprising:
a first substrate;
a photoelectric conversion unit provided in the first substrate;
a floating diffusion unit provided in the first substrate;
a pixel transistor electrically connected to the floating diffusion unit; and
a capacitor including a first electrode electrically connected or connectable to the pixel transistor, a second electrode different from the first electrode, and a first ferroelectric film or a first antiferroelectric film provided between the first electrode and the second electrode.

2. The solid-state imaging device according to claim 1, wherein the pixel transistor is an amplifying transistor having a gate electrically connected to the floating diffusion unit and a source or a drain electrically connected to or connectable to the first electrode.

3. The solid-state imaging device according to claim 1, wherein the first electrode is electrically connectable to the pixel transistor via a switch transistor.

4. The solid-state imaging device according to claim 1, wherein the first ferroelectric film or the first antiferroelectric film contains hafnium (Hf), zirconium (Zr), niobium (Nb), scandium (Sc), yttrium (Y), lanthanum (La), germanium (Ge), or silicon (Si).

5. The solid-state imaging device according to claim 1,
wherein the capacitor is provided on a first surface side of the first substrate, and
the solid-state imaging device further includes a lens provided on a second surface side of the first substrate.

6. The solid-state imaging device according to claim 1, further comprising a second substrate bonded to the first substrate,
wherein the pixel transistor and the capacitor are provided between the first substrate and the second substrate.

7. The solid-state imaging device according to claim 6,
wherein the pixel transistor is provided in a first insulating film provided on the first substrate, and
the capacitor is provided in a second insulating film provided on the second substrate and located between the second substrate and the first insulating film.

8. The solid-state imaging device according to claim 6, further comprising a third substrate provided between the first substrate and the second substrate,
wherein the capacitor is provided between the second substrate and the third substrate.

9. The solid-state imaging device according to claim 1, wherein a capacity of the capacitor is controlled to be set to only one of a plurality of types of values.

10. The solid-state imaging device according to claim 1, further comprising a memory including a third electrode and a fourth electrode different from the third electrode,
wherein the memory
includes a second ferroelectric film between the third electrode and the fourth electrode in a case where the capacitor includes the first ferroelectric film, and
includes a second antiferroelectric film between the third electrode and the fourth electrode in a case where the capacitor includes the first antiferroelectric film.

11. The solid-state imaging device according to claim 10,
wherein the third electrode is formed of the same material as the first electrode,
the fourth electrode is formed of the same material as the second electrode, and
the second ferroelectric film or the second antiferroelectric film is formed of the same material as the first ferroelectric film or the first antiferroelectric film.

12. A solid-state imaging device comprising:
a first substrate;
a photoelectric conversion unit provided in the first substrate;
a floating diffusion unit provided in the first substrate;
a capacitor including a first electrode provided on a first surface side or a second surface side of the first substrate, a second electrode different from the first electrode, and a first ferroelectric film, a first antiferroelectric film, or a first paraelectric film provided between the first electrode and the second electrode; and
a memory including a third electrode and a fourth electrode different from the third electrode,
wherein the memory
includes a second ferroelectric film between the third electrode and the fourth electrode in a case where the capacitor includes the first ferroelectric film,
includes a second antiferroelectric film between the third electrode and the fourth electrode in a case where the capacitor includes the first antiferroelectric film, and
includes a second paraelectric film between the third electrode and the fourth electrode in a case where the capacitor includes the first paraelectric film.

13. The solid-state imaging device according to claim 12,
wherein the third electrode is formed of the same material as the first electrode,
the fourth electrode is formed of the same material as the second electrode, and
the second ferroelectric film, the second antiferroelectric film, or the second paraelectric film is formed of the same material as the first ferroelectric film, the first antiferroelectric film, or the second paraelectric film.

14. The solid-state imaging device according to claim 12, wherein the first and second ferroelectric films, the first and second antiferroelectric films, or the first and second paraelectric films contain hafnium (Hf), zirconium (Zr), niobium (Nb), scandium (Sc), yttrium (Y), lanthanum (La), germanium (Ge), or silicon (Si).

15. The solid-state imaging device according to claim 12,
wherein the capacitor and the memory are provided on the first surface side of the first substrate, and
the solid-state imaging device further includes a lens provided on the second surface side of the first substrate.

16. The solid-state imaging device according to claim 12, further comprising a pixel transistor electrically connected to the floating diffusion unit,
wherein the first electrode is electrically connected or connectable to the pixel transistor.

17. The solid-state imaging device according to claim 16, further comprising a second substrate bonded to the first substrate,
wherein the pixel transistor, the capacitor, and the memory are provided between the first substrate and the second substrate.

18. The solid-state imaging device according to claim 17,
wherein the pixel transistor is provided in a first insulating film provided on the first substrate, and
the capacitor and the memory are provided in a second insulating film provided on the second substrate and located between the second substrate and the first insulating film.

19. The solid-state imaging device according to claim 17, further comprising a third substrate provided between the first substrate and the second substrate,
wherein the capacitor and the memory are provided between the second substrate and the third substrate.

20. The solid-state imaging device according to claim 12, wherein the capacitor and the memory have portions provided in the same transverse plane.
